(19) United States
(12) Patent Application Publication
(10) Pub. No.: US 2011/0249338 A1
(43) Pub. Date: Oct. 13, 2011

(54) MICROFABRICATED MEMBER AND METHOD FOR MANUFACTURING THE SAME, AND ETCHING APPARATUS

(75) Inventors: Sohmei Endoh, Miyagi (JP); Kazuya Hayashibe, Saitama (JP); Koichiro Shimizu, Miyagi (JP)

(73) Assignee: SONY CORPORATION, Tokyo (JP)

(21) Appl. No.: 12/919,666

(22) PCT Filed: Dec. 17, 2009
(86) PCT No.: PCT/JP2009/071520

§ 371 Date: Jan. 20, 2011

(30) Foreign Application Priority Data
Dec. 26, 2008 (JP) P2008-335102

(51) Int. Cl. G02B 1/11; G03F 7/20; C23F 1/08

(52) U.S. Cl. 359/601; 156/345.43; 430/323

(57) ABSTRACT

A method for manufacturing a microfabricated member includes the steps of forming an inorganic resist layer on a stamper having a curved surface, exposing and developing the inorganic resist layer formed on the stamper, so as to form a pattern on the inorganic resist layer, and placing the stamper, which is provided with the pattern on the inorganic resist layer, on an electrode having a curved surface nearly identical or analogous to the curved surface of the stamper and etching the stamper to form an uneven shape on the stamper surface, so as to produce a microfabricated member.

### TECHNICAL FIELD

The present invention relates to a microfabricated member and a method for manufacturing the same, and an etching apparatus used for producing the same. In particular, the present invention relates to a microfabricated member having a curved surface.

### BACKGROUND ART

In recent years, technologies of manufacturing microfabricated members have been variously examined. For example, for the purpose of preventing surface reflection of light, a technology of forming fine and dense uneven structures (moth-eye structure) on an optical element surface has been proposed (refer to, for example, “OPTICAL AND ELECTRO-OPTICAL ENGINEERING CONTACT”, Vol. 43, No. 11 (2005), 630-637).

In general, in the case where a periodical uneven shape is disposed on an optical element surface, diffraction occurs when light passes through there, a straight-ahead component of the transmitted light is reduced significantly. However, in the case where the pitch of the uneven shape is smaller than the wavelength of the transmitting light, diffraction does not occur. For example, when the uneven shape is rectangular, an effective antireflection effect can be obtained with respect to a single-wavelength light corresponding to the pitch, the depth, and the like.

The present inventors have proposed a method based on combination of an optical disk stamper forming process and an etching process as a method for manufacturing such a microfabricated member (refer to, for example, Japanese Unexamined Patent Application Publication No. 2008-176076). This method can form a structure in the shape of a temple bell or an elliptical truncated cone.

In a common optical disk stamper producing process, an uneven pattern is produced as described below. Initially, a solution, in which a resist serving as a photosensitive material is diluted with a thinner, is applied to a flat and smooth glass substrate by a spin coating method, so that a flat and smooth resist film having a uniform film thickness is formed on the substrate. Subsequently, various exposure patterns are recorded on the resist film of the substrate with an optical recording apparatus, and development is performed. Consequently, an uneven pattern having uniform depth and width is formed.

### DISCLOSURE OF INVENTION

### Technical Problem

In this regard, in recent years, for the purpose of preventing reflection and the like, it has been desired that the above-described uneven structure (moth-eye structure) is formed with respect to various optical components. In order to respond to these demands, a technology of forming a fine uneven pattern on a stamper having a curved surface, e.g., a spherical surface or a circular cylindrical surface, is required.

Accordingly, it is an object of the present invention to provide a microfabricated member having a fine uneven pattern on a curved surface, e.g., a spherical surface or a circular cylindrical surface, and a method for manufacturing the same, and an etching apparatus used for producing the same.

### Technical Solution

In order to solve the above-described problems, a first invention is

a method for manufacturing a microfabricated member, the method including the steps of

forming an inorganic resist layer on a stamper having a curved surface,

exposing and developing the inorganic resist layer formed on the stamper, so as to form a pattern on the inorganic resist layer, and

placing the stamper, which is provided with the pattern on the inorganic resist layer, on an electrode having a curved surface nearly identical or analogous to the curved surface of the stamper and etching the stamper to form an uneven shape on the stamper surface, so as to produce a microfabricated member.

A second invention is

a microfabricated member including

a substrate having a curved surface and

structures, which are convex portions or concave portions, formed on the curved surface of the substrate,

wherein the structures are arranged with a pitch less than or equal to the wavelength of the light in a use environment.

A third invention is

an etching apparatus including

an etching reaction vessel and

a first electrode and a second electrode, which are oppositely disposed in the etching reaction vessel,

wherein the first electrode has a placement surface for placing a substrate and

the placement surface has a curved surface or an uneven surface.

A fourth invention is

an optical element including

a substrate and

a large number of structures arranged on a surface of the substrate,

wherein the structures are arranged with a pitch less than or equal to the wavelength of the light in a use environment, and

the structures are disposed slantingly in at least two different directions at predetermined angles with respect to the direction normal to the surface of the substrate.

In the present invention, a tetragonal lattice refers to a lattice in the shape of a square. A quasi-tetragonal lattice refers to a lattice in the shape of a distorted square different from the lattice in the shape of a square. Specifically, in the case where the structures are arranged on a straight line, the quasi-tetragonal lattice refers to a tetragonal lattice obtained by stretching a lattice in the shape of a square in the direction of the arrangement in the shape of the straight line, so as to distort. In the case where the structures are arranged on an arc, the quasi-tetragonal lattice refers to a tetragonal lattice obtained by distorting a lattice in the shape of a square into the shape of an arc or a tetragonal lattice obtained by distorting a lattice in the shape of a square into the shape of an arc and, in addition, stretching in the direction of the arrangement in the shape of the arc, so as to distort.

In the present invention, a hexagonal lattice refers to a lattice in the shape of a regular hexagon. A quasi-hexagonal lattice refers to a lattice in the shape of a distorted regular hexagon different from the lattice in the shape of a regular hexagon. Specifically, in the case where the structures are arranged on a straight line, the quasi-hexagonal lattice refers to a hexagonal lattice obtained by stretching a lattice in the shape of a regular hexagon in the direction of the arrangement in the shape of the straight line, so as to distort. In the case where the structures are arranged on an arc, the quasi-hexagonal lattice refers to a hexagonal lattice obtained by distorting a lattice in the shape of a regular hexagon into the shape of an arc or a hexagonal lattice obtained by distorting a lattice in the shape of a regular hexagon into the shape of an arc and, in addition, stretching in the direction of the arrangement in the shape of the arc, so as to distort.

In the present invention, the stamper provided with the inorganic resist pattern is placed on the electrode having a curved surface nearly identical or analogous to the curved surface of the stamper and the stamper is etched, so that etching can be performed in a direction perpendicular to the curved surface of the stamper. Consequently, an uneven pattern having uniform depth and width can be formed with respect to a stamper having a curved surface, e.g., the shape of a circular cylinder, the shape of a sphere, and the like.

### Advantageous Effects

As described above, according to the present invention, a microfabricated member having a fine uneven pattern on a curved surface, e.g., a spherical surface or a circular cylindrical surface, and a method for manufacturing a microfabricated member can be realized.

### BRIEF DESCRIPTION OF DRAWINGS

FIG. 1A is a schematic plan view showing an example of the configuration of an optical element according to a first embodiment of the present invention. FIG. 1B is a magnified plan view illustrating a part of the optical element shown in FIG. 1A. FIG. 1C is a sectional view along a track T1, T3, . . . shown in FIG. 1B. FIG. 1D is a sectional view along a track T2, T4, . . . shown in FIG. 1B.

FIG. 2 is a magnified perspective view illustrating a part of the optical element shown in FIG. 1.

FIG. 3 A is a perspective view showing an example of the configuration of a master. FIG. 3 B is a magnified plan view illustrating a part of the master shown in FIG. 3 A.

FIG. 4 is a schematic diagram showing an example of the configuration of an exposing apparatus for producing a master.

FIG. 5 is a schematic diagram showing an example of the configuration of an etching apparatus for producing a master.

FIG. 6 A to FIG. 6 C are step diagrams for explaining a method for manufacturing an optical element according to a first embodiment of the present invention.

FIG. 7 A to FIG. 7 C are step diagrams for explaining the method for manufacturing an optical element according to the first embodiment of the present invention.

FIG. 8 is a schematic diagram showing an example of the configuration of an exposing apparatus used for manufacturing an optical element according to a second embodiment of the present invention.

FIG. 9 is a schematic diagram showing an example of the configuration of an exposing apparatus used for manufacturing an optical element according to the second embodiment of the present invention.

FIG. 10 A is a schematic plan view showing an example of the configuration of an optical element according to a fourth embodiment of the present invention. FIG. 10 B is a magnified plan view illustrating a part of the optical element shown in FIG. 10 A. FIG. 10 C is a sectional view along a track T1, T3, . . . shown in FIG. 10 B. FIG. 10 D is a sectional view along a track T2, T4, . . . shown in FIG. 10 B.

FIG. 11A is a schematic plan view showing an example of the configuration of an optical element according to a fifth embodiment of the present invention. FIG. 11B is a magnified plan view illustrating a part of the optical element shown in FIG. 11A. FIG. 11C is a sectional view along a track T1, T3, . . . shown in FIG. 11B. FIG. 11D is a sectional view along a track T2, T4, . . . shown in FIG. 11 B.

FIG. 12 A is a side view showing an example of the configuration of a master. FIG. 12 B is a magnified plan view illustrating a part of the master shown in FIG. 12 A.

FIG. 13 is a schematic diagram showing an example of the configuration of an exposing apparatus for producing a master.

FIG. 14 is a schematic diagram showing an example of the configuration of an etching apparatus for producing a master.

FIG. 15 A is a schematic plan view showing an example of the configuration of an optical element according to a sixth embodiment of the present invention. FIG. 15 B is a magnified plan view illustrating a part of the optical element shown in FIG. 15 A. FIG. 15 C is a sectional view along a track T1, T3, . . . shown in FIG. 15 B. FIG. 15 D is a sectional view along a track T2, T4, . . . shown in FIG. 15 B.

FIG. 16 is a magnified perspective view illustrating a part of the optical element shown in FIG. 15.

FIG. 17 A is a plan view showing an example of the configuration of a master. FIG. 17 B is a magnified plan view illustrating a part of the master shown in FIG. 17 A.

FIG. 18 is a schematic diagram showing an example of the configuration of an exposing apparatus for producing a master.

FIG. 19 is a schematic diagram showing an example of the configuration of an etching apparatus for producing a master.

FIG. 20 A to FIG. 20 C are step diagrams for explaining a method for manufacturing an optical element according to the sixth embodiment of the present invention.

FIG. 21A to FIG. 21C are step diagrams for explaining the method for manufacturing an optical element according to the sixth embodiment of the present invention.

FIG. 22 A is a schematic plan view showing an example of the configuration of an optical element according to a seventh embodiment of the present invention. FIG. 22 B is a magnified plan view illustrating a part of the optical element shown in FIG. 22 A. FIG. 22 C is a sectional view along a track T1, T3, . . . shown in FIG. 22 B. FIG. 22 D is a sectional view along a track T2, T4, . . . shown in FIG. 22 dB.

FIG. 23 is a magnified perspective view illustrating a part of the optical element shown in FIG. 22.

FIG. 24 is a sectional view showing an example of the configuration of a liquid crystal display device according to a ninth embodiment of the present invention.

FIG. 25 is a sectional view showing an example of the configuration of a liquid crystal display device according to a tenth embodiment of the present invention.

FIG. 26 A is a SEM photograph of an optical element according to Example 1. FIG. 26 B is a SEM photograph of an optical element according to Example 2. FIG. 26 C is a SEM photograph of an optical element according to Example 3.

FIG. 27 is a graph showing antireflection characteristics in Example 1.

FIG. 28 A is a perspective view showing an outward appearance of a moth-eye lens film in Example 4. FIG. 28 B is a sectional view along an A-A line shown in FIG. 28 A.

FIG. 29 A and FIG. 29 B are photographs showing outward appearances of a moth-eye quartz lens in Example 5.

### BEST MODES FOR CARRYING OUT THE INVENTION

The embodiments according to the present invention will be described in the following order with reference to the drawings. In this regard, in all of the following drawings of the embodiments, the same or corresponding portions are indicated by the same reference numerals.

(1) First embodiment (example of master in the shape of a circular cylinder)
(2) Second embodiment (example of exposure of stamper in the shape of a circular cylinder in landscape orientation)
(3) Third embodiment (example of arrangement of structures on inner perimeter surface of stamper in the shape of a circular cylinder)
(4) Fourth embodiment (example of arrangement of structures into the shape of tetragonal lattice)
(5) Fifth embodiment (example of production of master in the shape of a spherical surface)
(6) Sixth embodiment (master having inclined structures)
(7) Seventh embodiment (example of formation of concave structures on substrate surface)
(8) Eighth embodiment (example of direct transfer of uneven pattern of resist layer)
(9) Ninth embodiment (first example of application to display device)
(10) Tenth embodiment (second example of application to display device)

### 1. First Embodiment

### Configuration of Optical Element

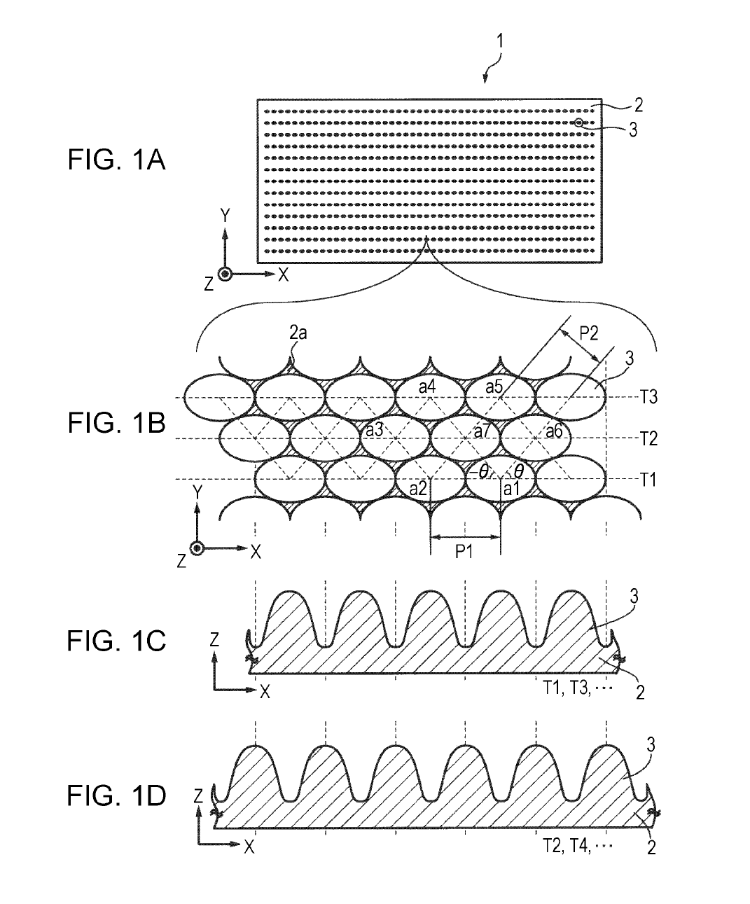

FIG. 1A is a schematic plan view showing an example of the configuration of an optical element according to a first embodiment of the present invention. FIG. 1B is a magnified plan view illustrating a part of the optical element shown in FIG. 1A. FIG. 1C is a sectional view along a track T1, T3, . . . shown in FIG. 1B. FIG. 1D is a sectional view along a track T2, T4, . . . shown in FIG. 1B.

This optical element 1 is favorably applied to various optical components, e.g., displays, optoelectronics, optical communications (optical fibers), solar cells, and illumination apparatuses. Specific examples of optical components can include any one type of polarizers, lenses, light guide plates, window materials, and display elements.

An optical element 1 includes a substrate 2 and structures 3, which are convex portions disposed on a surface of this substrate 2. This optical element 1 has a function to prevent reflection of light incident on the substrate surface provided with the structures 3. Hereafter, as shown in FIG. 1, two axes orthogonal to each other in one principal surface of the substrate 2 are referred to as an X axis and a Y axis, and the axis perpendicular to the one principal surface of the substrate 2 is referred to as a Z axis. Furthermore, in the case where gap portions 2a are present between the structures 3, it is preferable that fine uneven shapes are disposed in the gap portions 2a. The reason therefor is that the reflectance of the optical element 1 can be further reduced by disposing the above-described fine uneven shapes.

The substrate 2 and the structures 3, which constitute the optical element 1, will be sequentially described below.

### (Substrate)

The substrate 2 is a transparent substrate having transparency. Examples of materials for the substrate 2 include materials containing transparent synthetic resins, e.g., polycarbonate (PC) and polyethylene terephthalate (PET), glass, and the like as primary components, although not specifically limited to these materials.

Examples of shapes of the substrate 2 can include the shape of a film, the shape of a sheet, the shape of a plate, and the shape of a block, although not specifically limited to these shapes. It is preferable that the shape of the substrate 2 is selected and determined in accordance with the shapes of main body portions of various optical devices, e.g., displays, optoelectronics, optical communications, solar cells, and illumination apparatuses, which are required to have a predetermined antireflection function, and components with the antireflection function, which are in the shape of a sheet, a film, or the like and which are attached to these optical devices.

### (Structures)

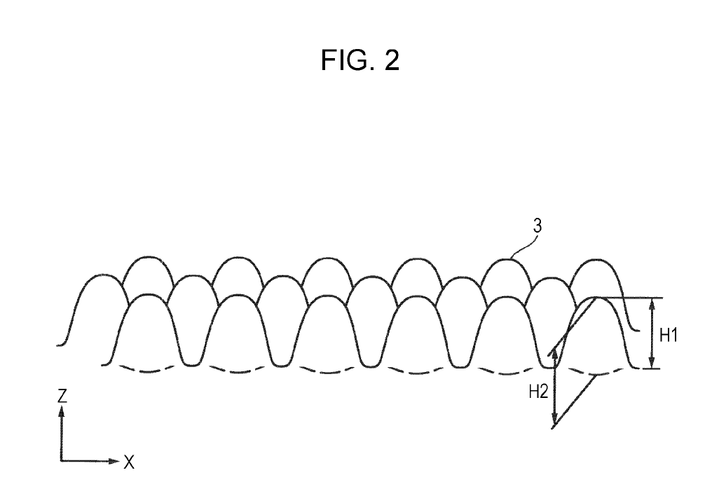

FIG. 2 is a magnified perspective view illustrating a part of the optical element shown in FIG. 1. A large number of structures 3, which are convex portions, are arranged on a surface of the substrate 2. These structures 3 are periodically two-dimensionally arranged with a short pitch smaller than or equal to the wavelength of the light in a use environment, for example, with the same level of pitch as the wavelength of the visible light. The light in a use environment is, for example, ultraviolet light, visible light, or infrared light. Here, the ultraviolet light refers to the light having a wavelength within the range of 10 nm or more, and less than 360 nm, the visible light refers to the light within the range of 360 nm or more, and 830 nm or less, and the infrared light refers to the light within the range of more than 830 nm, and 1 mm or less.

The structures 3 of the optical element 1 have an arrangement form constituting a plurality of tracks T1, T2, T3, . . . (hereafter may be generically referred to as “track T”) on the surface of the substrate 2. Here, the track refers to a portion, in which the structures 3 are lined up while being aligned into the shape of a straight line. The lower portions of the adjacent structures 3 may be overlapped, and the lower portions of the structures 3 may be mutually joined. The joining of the structures 3 is performed between all or a part of the structures 3, which are in the relationship of being adjacent. For example, the lower portions of the structures 3 arranged in the track direction are mutually overlapped and are joined. The reflection characteristic can be improved by mutually joining the lower portions of the structures 3.

The structures 3 are arranged in such a way that positions in adjacent two tracks T are displaced a half pitch with respect to each other. Specifically, regarding the adjacent two tracks T, the structures 3 of one track (for example, T2) are arranged at midpoint positions (positions displaced a half pitch) of the structures 3 arranged in the other track (for example, T1). As a result, as shown in FIG. 1B, regarding the adjacent three lines of tracks (T1 to T3), the structures 3 are arranged in such a way as to form a hexagonal lattice pattern or a quasi-hexagonal lattice pattern, in which the centers of the structures 3 are located at individual points a1 to a7. In the present first embodiment, the hexagonal lattice pattern refers to a lattice pattern in the shape of a regular hexagon. Furthermore, the quasi-hexagonal lattice pattern is different from the lattice pattern in the shape of a regular hexagon and refers to a hexagonal lattice pattern stretched in an extension direction of the track (X axis direction) so as to distort.

In the case where the structures 3 are arranged in such a way as to form a quasi-hexagonal lattice pattern, as shown in FIG. 1B, it is preferable that the arrangement pitch P1 (the distance between a1 and a2) of the structures 3 in the same track (for example, T1) is larger than the arrangement pitch of the structures 3 in adjacent two tracks (for example, tracks T1 and T2), that is, the arrangement pitch P2 (for example, the distance between a1 and a7, a2 and a7) of the structures 3 in ±θ directions with respect to the extension direction of the track. It becomes possible to further improve the packing density of the structures 3 by arranging the structures 3 as described above.

The height of the structure 3 is not specifically limited and is set appropriately in accordance with the wavelength region of the light to be transmitted. The height of the structure 3 is, for example, 236 nm to 450 nm, and preferably 415 nm to 421 nm. It is preferable that the aspect ratio (height H/arrangement pitch P) of the structure 3 is set within the range of 0.81 to 1.46. The reason therefor is that if the aspect ratio is less than 0.81, the reflection characteristic and the transmission characteristic tend to be reduced, and if 1.46 is exceeded, the peeling characteristic tends to be reduced in production of the optical element 1 and a duplicate of a replica tends to become difficult to take off.

In this regard, the aspect ratio in the present invention is defined by the following formula (1).

aspect ratio=H/P (1)

where, H: height of structure 3, P: average arrangement pitch (average period)

Here, the average arrangement pitch P is defined by the following formula (2).

average arrangement pitch P=(P1+P2+P2)/3 (2)

where, P1: arrangement pitch in extension direction of track (period in extension direction of track), P2: arrangement pitch in ±θ direction (where, θ=60°−δ, here, δ is preferably 0°<δ≦11°, and more preferably 3°≦δ≦6° with respect to extension direction of track (period in θ direction)

In this regard, the height H of the structures 3 is assumed to be the height H2 in the direction of lines of the structures 3 (refer to FIG. 2). Here, the direction of lines refers to a direction (Y axis direction) orthogonal to the extension direction of the track (X axis direction) in the substrate surface. In the case where the optical element 1 is produced by a manufacturing method described later, it is preferable that the height H1 of the structures 3 in the track extension direction is made smaller than the height H2 in the direction of lines. If such a relationship in the height is employed, in the manufacturing method described later, the heights of the structures 3 of the portions in the directions other than the track extension direction become nearly equal to the height H2 in the direction of lines. Therefore, the height H of the structures 3 is represented by the height H2 in the direction of lines.

In FIG. 2, the individual structures 3 have the same shape. However, the shape of the structure 3 is not limited to this. The structures 3 having at least two types of shapes may be disposed on the substrate surface. Furthermore, the structures 3 may be formed integrally with the substrate 2.

In this regard, the aspect ratios of the structures 3 are not always the same in all cases. The structures 3 may be configured to have certain height distribution (for example, the aspect ratio within the range of about 0.83 to 1.46). The wavelength dependence of the reflection characteristic can be reduced by disposing the structures 3 having the height distribution. Consequently, the optical element 1 having excellent antireflection characteristic can be realized.

Here, the height distribution refers to that the structures 3 having at least two types of heights (depths) are disposed on the surface of the substrate 2. That is, it is referred to that the structures 3 having the height serving as the reference and structures 3 having the heights different from the height of the above-described structures 3 are disposed on the surface of the substrate 2. For example, the structures 3 having the heights different from the reference are periodically or aperiodically (randomly) disposed on the surface of the substrate 2. Examples of directions of the periodicity include the extension direction of the track and the direction of lines.

As for the material for the structure 3, for example, materials containing an ionizing radiation curable resin, which is cured by ultraviolet rays or electronic beams, or a thermosetting resin, which is cured by heat, as a primary component are preferable, and materials containing a ultraviolet curable resin, which can be cured by ultraviolet rays, as a primary component are most preferable.

It is preferable that the structure 3 has a curved surface, which is extended gradually from the top portion toward the bottom portion of this structure 3. The reason therefor is that the transferability can be made good by employing such a shape.

The top portion of the structure 3 is, for example, a flat surface or a convexly curved surface, and preferably a convexly curved surface. The durability of the optical element 1 can be improved by employing the convexly curved surface as described above. Alternatively, a low-refractive index layer having a refractive index lower than that of the structure 3 may be disposed on the top portion of the structure 3. The reflectance can be reduced by disposing such a low-refractive index layer.

Examples of whole shapes of the structure 3 can include the shape of a cone. Examples of the shape of a cone can include the shape of a circular cone, the shape of a circular truncated cone, the shape of an elliptical cone, the shape of an elliptical truncated cone, the shape of a circular cone having a curvature at the top portion, and the shape of an elliptical cone having a curvature at the top portion. Here, the shape of a cone is a concept including the shape of an elliptical cone, the shape of an elliptical truncated cone, the shape of a circular cone having a curvature at the top portion, and the shape of an elliptical cone having a curvature at the top portion besides the shape of a circular cone and the shape of a circular truncated cone. In this regard, the shape of a circular truncated cone refers to the shape, in which the top portion of the shape of a circular cone has been cut off, and the shape of an elliptical truncated cone refers to the shape, in which the top portion of the shape of an elliptical cone has been cut off. Furthermore, the whole shape of the structure 3 is not limited to these shapes and can be selected appropriately in accordance with the desired characteristics.

More specifically, the structure 3 having the shape of an elliptical cone is a structure having a cone structure, in which the bottom is in the shape of an ellipse, an oval, or an egg having a major axis and a minor axis and the top portion is a curved surface. The structure 3 having the shape of an elliptical truncated cone is a structure having a cone structure, in which the bottom is in the shape of an ellipse, an oval, or an egg having a major axis and a minor axis and the top portion is flat. In the case where the structure 3 is in the shape of an elliptical cone or the shape of an elliptical truncated cone, it is preferable to form the structure 3 on the substrate surface in such a way that the direction of the major axis of the bottom of the structure 3 becomes the extension direction of the track (X axis direction).

### [Configuration of Master]

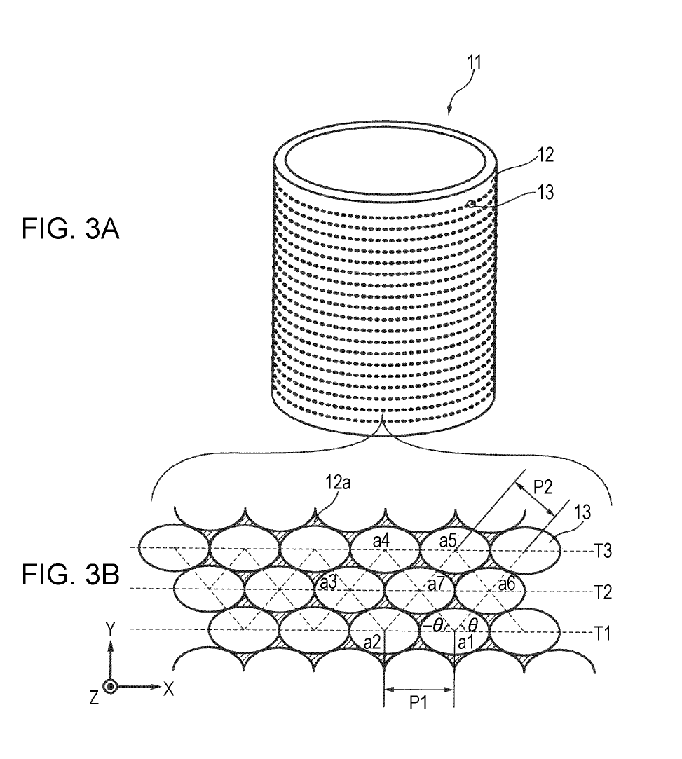

FIG. 3 shows an example of the configuration of a master for producing the optical element having the above-described configuration. As shown in FIG. 3, a master 11 is a so-called roll master and has the configuration, in which a large number of structures 13 composed of concave portions are arranged on the surface of a stamper 12 in the shape of a circular cylinder. These structures 13 are periodically two-dimensionally arranged with a pitch smaller than or equal to the wavelength of the light in a use environment of the optical element 1, for example, with the same level of pitch as the wavelength of the visible light. The structures 13 are disposed on the shape of concentric circles or the shape of a spiral on the surface of the stamper 12 in the shape of a circular cylinder. The structures 13 are to form structures 3, which are convex portions, on the surface of the above-described substrate 2. As for the material for the stamper 12, for example, glass can be used, although not specifically limited to this material.

### [Configuration of Exposing Apparatus]

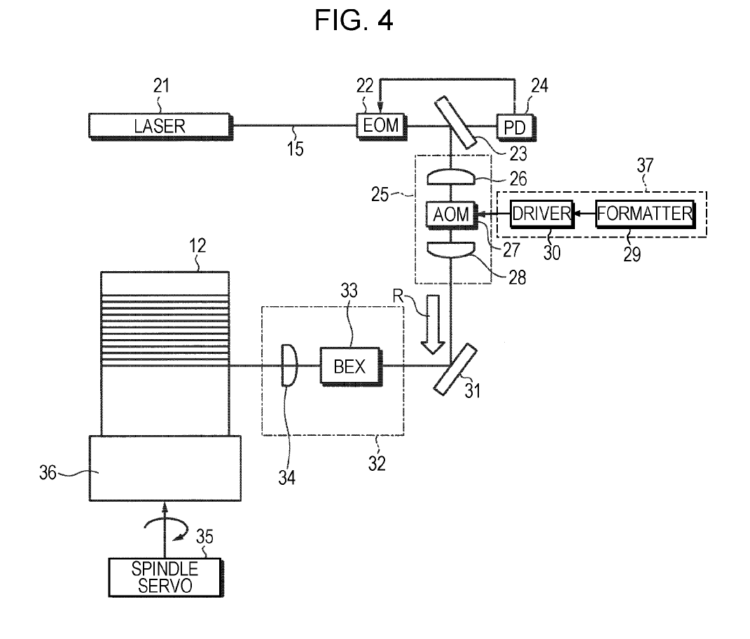

FIG. 4 is a schematic diagram showing an example of the configuration of an exposing apparatus for producing a master having the above-described configuration. This exposing apparatus is formed on the basis of an optical disk recording apparatus.

A laser light source 21 is a light source to expose a resist applied as a film on the surface of the stamper 12 serving as a recording medium and is to lase the recording laser light 15 with a wavelength λ=266 nm, for example. The laser light 15 emitted from the laser light source 21 moves in a straight line while being in the state of a collimated beam and enters an electro optical modulator (EOM: Electro Optical Modulator) 22. The laser light 15 passed through the electro optical modulator 22 is reflected at a mirror 23, and is led to a modulation optical system 25.

The mirror 23 is formed from a polarizing beam splitter, and has a function of reflecting one polarized component and transmitting the other polarized component. The polarized component passed through the mirror 23 is received with a photodiode 24, and the electro optical modulator 22 is controlled on the basis of the received light signal, so that phase modulation of the laser light 15 is performed.

In the modulation optical system 25, the laser light 15 is condensed on an acoust-optic modulator (AOM: Acoust-Optic Modulator) 27, composed of glass (SiO₂) or the like with a condenser lens 26. The laser light 15 is subjected to intensity modulation with the acoust-optic modulator 27, so as to diverge and, thereafter, is converted to a collimated beam with a collimator lens 28. The laser light 15 emitted from the modulation optical system 25 is reflected at a mirror 31 and is led on a moving optical table 32 horizontally and in parallel.

The moving optical table 32 is provided with a beam expander 33 and an objective lens 34. The laser light 15 led to the moving optical table 32 is shaped into a desired beam shape with the beam expander 33 and, thereafter, is applied to the resist layer on the stamper 12 through the objective lens 34. The stamper 12 is placed on a turn table 36 connected to a spindle motor 35. Then, the laser light 15 is applied to the resist layer intermittently while the stamper 12 is rotated and, in addition, the laser light 15 is moved in the height direction of the stamper 12, so that an exposure step of the resist layer is performed. The formed latent image takes the shape of, for example, nearly an ellipse having a major axis in the circumferential direction. The movement of the laser light 15 is performed by moving the moving optical table 32 in the direction indicated by an arrow R.

The exposing apparatus is provided with a control mechanism 37 to form a latent image corresponding to the two-dimensional pattern of the hexagonal lattice or the quasi-hexagonal lattice shown in FIG. 1B on the resist layer. The control mechanism 37 is provided with a formatter 29 and a driver 30. The formatter 29 is provided with a polarity inversion portion. This polarity inversion portion controls the application timing of the laser light 15 to the resist layer. The driver 30 receives the output from the polarity inversion portion and controls the acoust-optic modulator 27.

In this exposing apparatus, a polarity inversion formatter signal and a rotation controller of the recording apparatus are synchronized to generate a signal and intensity modulation is performed with the acoust-optic modulator 27 on a track basis in such a way that the two-dimensional patterns are linked spatially. The hexagonal lattice or quasi-hexagonal lattice pattern can be recorded on the resist layer by performing patterning at a constant angular velocity (CAV: Constant Angular Velocity) and the appropriate number of revolutions with an appropriate modulation frequency and an appropriate feed pitch.

### [Configuration of Etching Apparatus]

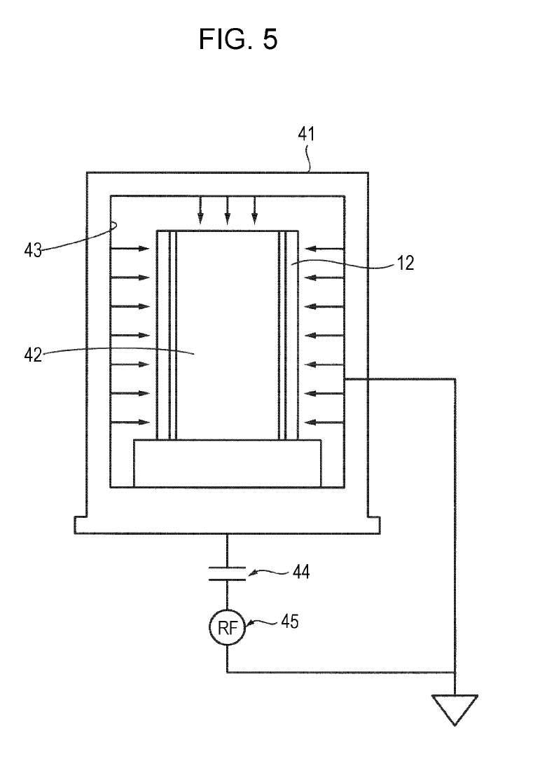

FIG. 5 is a schematic diagram showing an example of the configuration of an etching apparatus for producing a master having the above-described configuration. The etching apparatus is a so-called RIE (Reactive Ion Etching) apparatus and is provided with an etching reaction vessel 41, a circular cylindrical electrode 42 serving as a cathode (negative electrode), and a counter electrode 43 serving as an anode (positive electrode), as shown in FIG. 5. The circular cylindrical electrode 42 is disposed at the center of the etching reaction vessel 41. The counter electrode 43 is disposed in the inner side of the etching reaction vessel 41. The circular cylindrical electrode 42 has a configuration, in which the stamper 12 in the shape of a circular cylinder can be removably attached thereto. The circular cylindrical electrode 42 has, for example, a circular cylindrical surface nearly identical or analogous to the circular cylindrical surface of the cylindrical stamper 12, specifically a circular cylindrical surface having a diameter somewhat smaller than that of the inner perimeter surface of stamper 12 in the shape of a circular cylinder. The circular cylindrical electrode 43 is connected to, for example, 13.56 MHz of high-frequency power supply (RF) 45 with a blocking capacitor 44 therebetween. The counter electrode 43 is connected to the ground.

In the etching apparatus having the above-described configuration, when a high-frequency voltage is applied between the counter electrode 43 and the circular cylindrical electrode 42 by the high-frequency power supply 45, plasma is generated between the counter electrode 43 and the circular cylindrical electrode 42. The counter electrode 43 is connected to the ground, so that the potential is not changed, whereas the potential of the circular cylindrical electrode 42 becomes negative because the circuit is interrupted by the blocking capacitor 44 and voltage drop occurs. Because of this voltage drop, an electric field is generated in a direction perpendicular to the circular cylindrical surface of the circular cylindrical electrode 42, positive ions in the plasma enter the outer perimeter surface of the stamper 12 in the shape of a circular cylinder perpendicularly, so that anisotropic etching is effected.

### [Method for Manufacturing Optical Element]

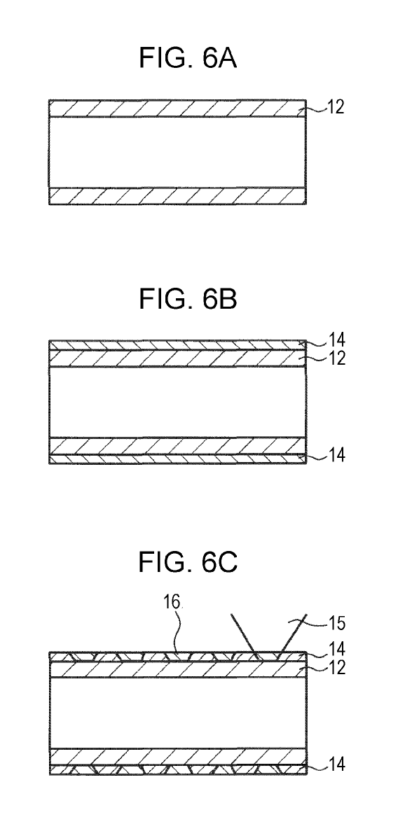

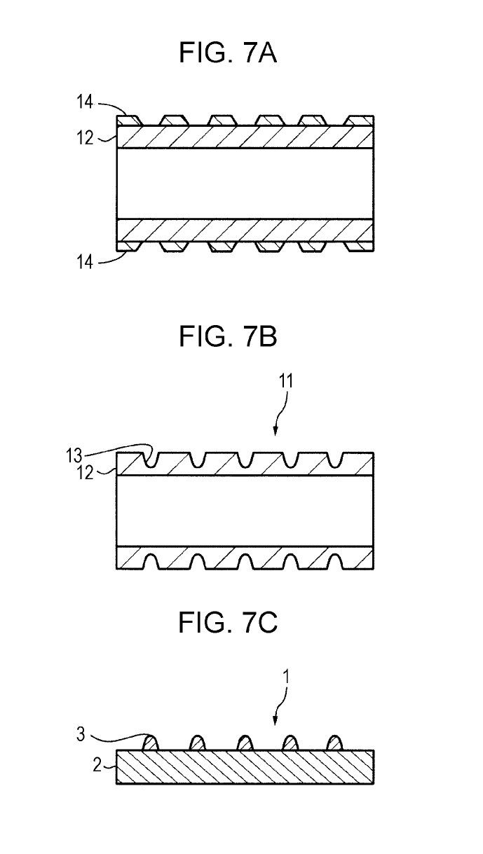

A method for manufacturing an optical element according to the first embodiment of the present invention will be described with reference to FIG. 6 and FIG. 7.

The method for manufacturing an optical element according to the first embodiment is a method based on combination of an optical disk stamper forming process and an etching process. This manufacturing method includes a resist film formation step to form a resist layer on a stamper, an exposure step to form a latent image on the resist layer by using an exposing apparatus, a development step to develop the resist layer provided with the latent image, an etching step to produce a master through etching, and a duplicate step to produce a duplicate substrate from an ultraviolet curable resin.

The individual steps of the method for manufacturing an optical element according to the first embodiment of the present invention will be sequentially described below.

### (Resist Film Formation Step)

Initially, as shown in FIG. 6 A, a stamper 12 in the shape of a circular cylinder is prepared. This stamper 12 is, for example, a glass stamper. Subsequently, as shown in FIG. 6 B, an inorganic resist layer 14 is formed on the outer perimeter surface of the stamper 12 in the shape of a circular cylinder by a sputtering method. As for the inorganic resist, for example, a metal oxide formed from at least one type of transition metal, e.g., tungsten and molybdenum, can be used.

### (Exposure Step)

Then, as shown in FIG. 6 C, the exposing apparatus shown in FIG. 4 is used, the stamper 12 is rotated and, in addition, the laser light (exposure beam) 15 is applied to the inorganic resist layer 14. At this time, the laser light 15 is applied intermittently while the laser light 15 is moved in the height direction of the stamper 12 and, thereby, all over the surface of the inorganic resist layer 14 is exposed. In this manner, a latent image 16 in accordance with the locus of the laser light 15 is formed all over the inorganic resist layer 14 with, for example, the same level of pitch as the wavelength of the visible light.

### (Development Step)

Next, a developing solution is dropped on the inorganic resist layer 14 while the stamper 12 is rotated, so that the inorganic resist layer 14 is subjected to a developing treatment, as shown in FIG. 7 A. In the case where the inorganic resist layer 14 is formed from a positive type resist, the exposed portion exposed with the laser light 15 has an increased dissolution rate with respect to the developing solution as compared with that of the non-exposed portion. Therefore, as shown in FIG. 7 A, a pattern in accordance with the latent image (exposed portion) 16 is formed on the inorganic resist layer 14.

### (Etching Step)

Subsequently, the etching apparatus shown in FIG. 5 is used, and the surface of the stamper 12 is subjected to an etching treatment while the pattern (resist pattern) of the inorganic resist layer 14 formed on the stamper 12 serves as a mask. In this manner, as shown in FIG. 7 B, concave portions in the shape of an elliptical cone or the shape of an elliptical truncated cone having a major axis direction in the extension direction of the track, that is, structures 13, can be obtained.

Moreover, as necessary, the etching treatment and an ashing treatment may be performed alternately. Consequently, the structures 13 having various curved surfaces can be formed. For example, the shape of the structure 3 can be made into the shape of an elliptical cone, in which the slope of the top portion is gentle and the slope becomes sharp gradually from the central portion toward the bottom portion, by performing ashing and etching alternately and repeatedly and, in addition, increasing the time of the etching gradually. Furthermore, a glass master having a depth 3 times or more of the inorganic resist layer 14 (selection ratio of 3 or more) can be produced, so that it is possible to achieve an increase in the aspect ratio of the structure 3.

Consequently, a master 11 having a hexagonal lattice pattern or a quasi-hexagonal lattice pattern is obtained.

### (Duplicate Step)

Then, the master 11 and the substrate 2, e.g., an acrylic sheet coated with an ultraviolet curable resin, are closely adhered, and ultraviolet rays are applied, so as to cure the ultraviolet curable resin. Thereafter, the substrate 2 is peeled off the master 11. In this manner, as shown in FIG. 7 C, a desired optical element 1 is produced.

According to the first embodiment, the inorganic resist layer 14 is formed by the sputtering method and, thereby, a flat and smooth inorganic resist film having a uniform film thickness can be formed on the surface of the stamper 12 in the shape of a circular cylinder. Furthermore, the stamper 12 in the shape of a circular cylinder is placed on the circular cylindrical electrode 42 and reactive ion etching is performed, so that positive ions can enter the outer perimeter of the stamper 12 in the shape of a circular cylinder perpendicularly and anisotropic etching can be effected. In this manner, an uneven pattern having uniform depth and width can be formed on the stamper 12 having a circular cylindrical surface.

Moreover, in the case where the optical element 1 is produced by using a method based on combination of the optical disk stamper forming process and the etching process, the time (exposure time) required for the stamper production process can be reduced significantly as compared with that in the case where the optical element 1 is produced by using electron beam exposure. Therefore, the productivity of the optical element 1 can be improved significantly.

In addition, in the case where the shape of the top portion of the structure 3 is made into a smooth shape rather than a sharp shape, for example, a smooth curved surface protruding toward the height direction, the durability of the optical element 1 can be improved. Furthermore, the releasability of the optical element 1 with respect to the master 11 can also be improved.

Regarding an organic resist film forming process by a common spin coating method, in the case where a stamper has a curved surface (the shape of a circular cylinder, the shape of a sphere), variations in coating occur, and it is difficult to form a flat and smooth resist film having a uniform film thickness. Therefore, it is difficult to form an uneven pattern having uniform depth and width on the stamper surface in the shape of a curved surface. On the other hand, in the first embodiment, the inorganic resist layer 14 is formed by the sputtering method, so that a flat and smooth inorganic resist film having a uniform film thickness can be formed on the surface of the stamper 12 in the shape of a circular cylinder. Consequently, an uneven pattern having uniform depth and width can be formed on the stamper surface in the shape of a curved surface.

Moreover, the above-described manufacturing method is applied and, thereby, an uneven pattern having uniform depth and width can be formed with respect to those other than the stampers having curved surfaces, e.g., the shape of a circular cylinder and the shape of a sphere. For example, an uneven pattern having uniform depth and width can be formed with respect to stampers in, for example, the shape of a sheet, the shape of a tape, the shape of a rod, the shape of a needle, the shape of a rectangular parallelepiped (the shape of a box), the shape of a wire frame, and the shape of a circular cylinder. In addition, an uneven pattern having uniform depth and width can be formed with respect to the inside of a hollow substrate having the shape of a rectangular parallelepiped and a hollow stamper having the shape of a circular cylinder.

### 2. Second Embodiment

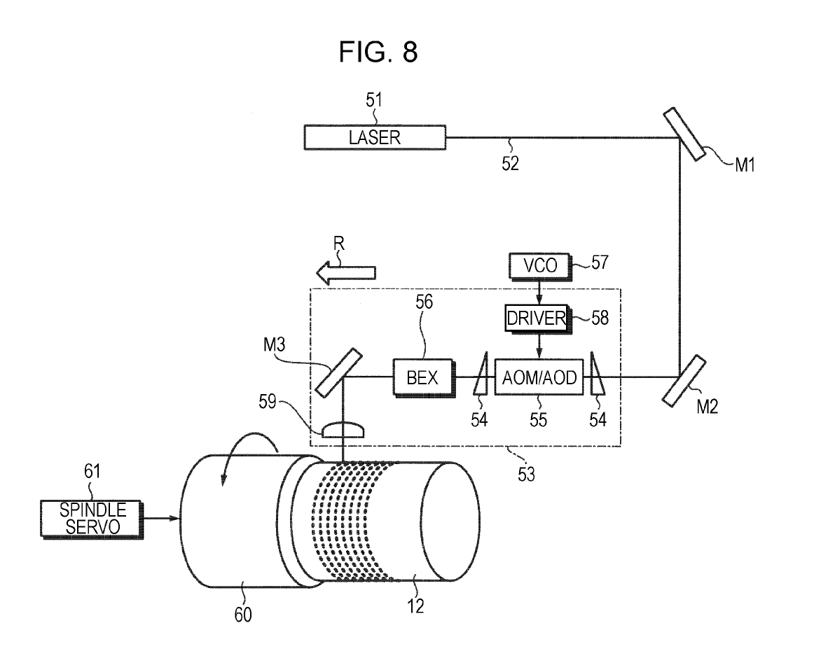

FIG. 8 is a schematic diagram showing an example of the configuration of an exposing apparatus used for manufacturing an optical element according to a second embodiment of the present invention. As shown in FIG. 8, the second embodiment is different from the first embodiment in that the stamper 12 in the shape of a circular cylinder is exposed in landscape orientation.

This exposing apparatus is provided with a turn table 60, a spindle servo 61, a laser light source 51 (266 nm), a mirror M1 and a mirror M2, a drive circuit (driver) 58, a moving optical table 53, a voltage frequency controller 57, an air slider (not shown in the drawing), a feed servo (not shown in the drawing), a focus servo (not shown in the drawing) of a skew method (Skew Method) as main portions thereof.

A laser light source 51 is a light source to expose a resist applied as a film on the surface of the circular cylindrical stamper 12 serving as a recording medium and is to lase the recording laser light 52 with a wavelength λ=266 nm, for example. However, the exposure light source is not specifically limited to merely such a laser light source 51. The laser light 52 emitted from this laser light source 51 moves in a straight line while being in the state of a collimated beam, and is reflected at the mirror M1 and the mirror M2 so as to be changed in direction and be led to a moving optical table 53.

Two wedge prisms 54 and one acoustic optical modulator/acoustic optical deflector (AOM/AOD; Acoustic Optical Modulator/Acoustic Optical Deflector) 55 are disposed on the moving optical table 53. These wedge prisms 54 and acoustic optical modulator/acoustic optical deflector 55 are disposed in such a way that the laser light 52 incident while being in the state of a collimated beam and a lattice face satisfy the Bragg's condition and, in addition, the beam horizontal height is not changed. As for an electro optical modulator used for the acoustic optical modulator/acoustic optical deflector 55, quartz (SiO₂) is favorable.

A predetermined signal is fed to the acoustic optical modulator/acoustic optical deflector 55 from the drive circuit 58. A high-frequency signal is supplied from the voltage frequency controller (VCO) 57 to the drive circuit 58. A control signal is fed to the voltage frequency controller 57. The acoustic optical modulator/acoustic optical deflector 55 takes advantage of the fact that the first-order diffracted light intensity in the Bragg diffraction is nearly proportional to an ultrasonic power, and modulate the ultrasonic power on the basis of the recording signal, so as to perform optical modulation of the laser light 52 and form a predetermined exposure pattern. In order to realize the Bragg diffraction, the positional relationship of the acoustic optical modulator/acoustic optical deflector 55 relative to the optical axis of the laser light 52 and the posture are set in such a way as to satisfy the Bragg's condition; 2dsin θ=nλ (where d: lattice spacing, λ: laser light wavelength, θ=angle between the laser light and the lattice face, and n: an integer). The lattice spacing d is changed by a control signal (signal to form wobble) from the voltage frequency controller 57, and θ is changed on the basis of the Bragg's condition (2dsin θ=nλ), so that deflection (wobble) occurs.

The thus modulated and deflected (wobbled) laser light 52 is shaped into a desired beam shape with a beam expander 56 and, thereafter, is applied to the inorganic resist of the stamper 12 in the shape of a circular cylinder with a mirror M3 and an objective lens 59, so as to form a latent image of a desired structure. Regarding an optical recording apparatus, the number of revolutions is controlled by a spindle servo, the feed of an air slider is controlled by a feed servo, the focus is controlled by a focus servo, so that exposure as shown in FIG. 8 is performed.

### 3. Third Embodiment

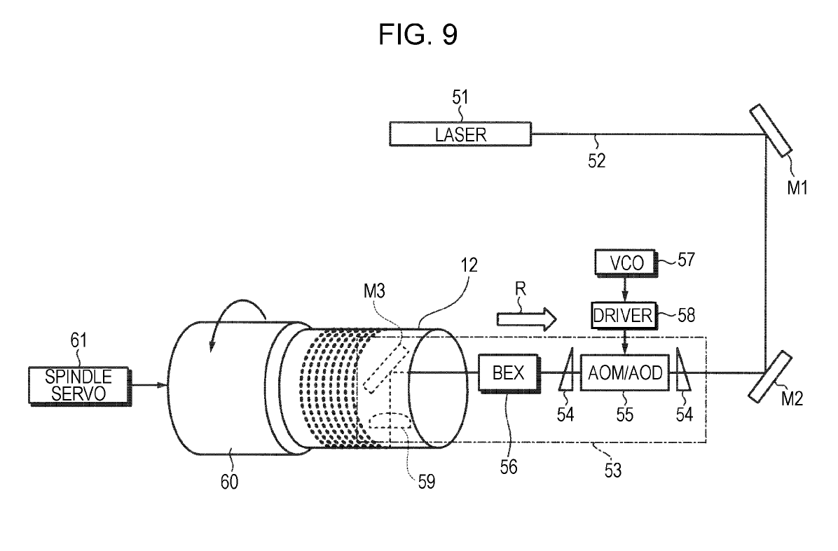

FIG. 9 is a schematic diagram showing an example of the configuration of an exposing apparatus used for manufacturing an optical element according to the second embodiment of the present invention. As shown in FIG. 9, the third embodiment is different from the second embodiment in that an inorganic resist layer is formed on an inner perimeter surface of the stamper 12 in the shape of a circular cylinder, and the resulting inorganic resist layer is exposed.

### 4. Fourth Embodiment

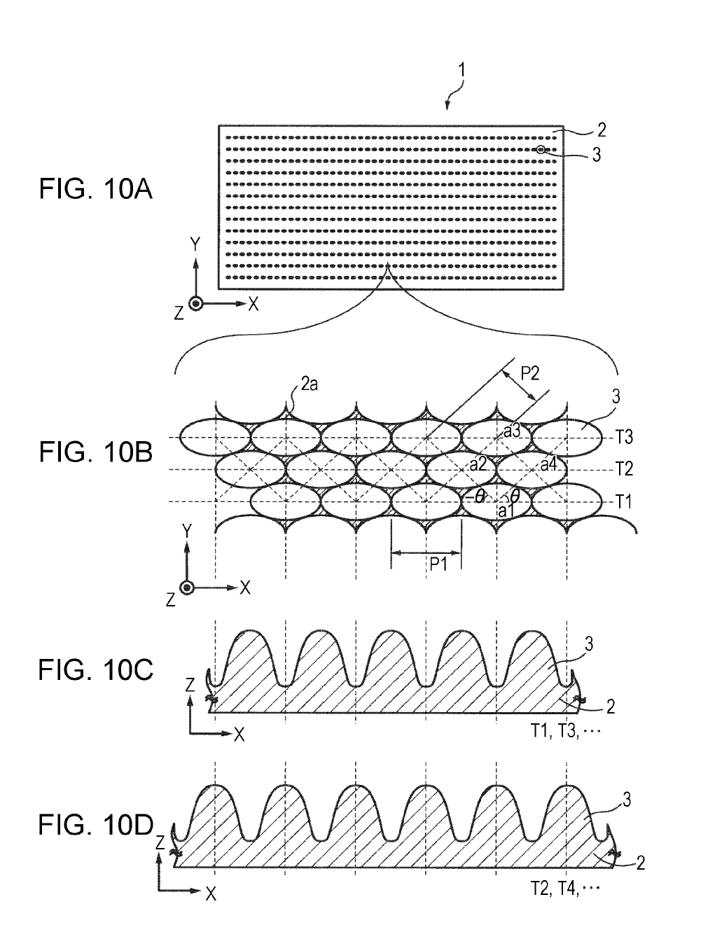

FIG. 10 A is a schematic plan view showing an example of the configuration of an optical element according to a fourth embodiment of the present invention. FIG. 10 B is a magnified plan view illustrating a part of the optical element shown in FIG. 10 A. FIG. 10 C is a sectional view along a track T1, T3, . . . shown in FIG. 10 B. FIG. 10 D is a sectional view along a track T2, T4, . . . shown in FIG. 10 B.

An optical element 1 according to the fourth embodiment is different from the optical element 1 of the first embodiment in that regarding the adjacent three lines of tracks, structures 3 constitute a tetragonal lattice pattern or a quasi-tetragonal lattice pattern. Here, the quasi-tetragonal lattice pattern is different from the regular tetragonal lattice pattern and refers to a tetragonal lattice pattern stretched in an extension direction of the track (X axis direction) so as to distort. In the case where the structures 3 are periodically arranged in the tetragonal lattice pattern or the quasi-tetragonal lattice pattern, for example, the structures 3 adjoin in an azimuth, in which the structures 3 have fourfold symmetry. Furthermore, in the case where the tetragonal lattice is further stretched and distorted, it becomes possible to adjoin to the structures 3 in the same track, and high packing density arrangement is achieved, where the structures 3 adjoin at two places in the same track direction in addition to the azimuth, in which fourfold symmetry is exhibited.

Regarding the adjacent two tracks T, the structures 3 of one track (for example, T2) are arranged at midpoint positions (positions displaced a half pitch) of the structures 3 arranged in the other track (for example, T1). As a result, as shown in FIG. 10 B, regarding the adjacent three lines of tracks (T1 to T3), the structures 3 are arranged in such a way as to form a tetragonal lattice pattern or a quasi-tetragonal lattice pattern, in which the centers of the structures 3 are located at individual points a1 to a4.

The height (depth) of the structure 3 is not specifically limited and is set appropriately in accordance with the wavelength region of the light to be transmitted. For example, in the case where the visible light is transmitted, it is preferable that the height (depth) of the structure 3 is 150 nm to 500 nm. The pitch P2 in a θ direction with respect to the track T is, for example, about 275 nm to 297 nm. The aspect ratio (height H/arrangement pitch P) of the structures 3 is, for example, about 0.54 to 1.13. Furthermore, the aspect ratios of the structures 3 are not always the same in all cases. The structures 3 may be configured to have certain height distribution.

It is preferable that the arrangement pitch P1 of the structures 3 in the same track is larger than the arrangement pitch P2 of the structures 3 between adjacent two tracks. Moreover, it is preferable that the ratio P1/P2 satisfies the relationship represented by 1.4<P1/P2≦1.5, where the arrangement pitch of the structures 3 in the same track is assumed to be P1 and the arrangement pitch of the structures 3 between adjacent two tracks is assumed to be P2. In the case where the above-described numerical range is employed, the filling factor of the structures having the shape of an elliptical cone or the shape of an elliptical truncated cone can be improved and, thereby, the antireflection characteristic can be improved.

In the fourth embodiment, as in the above-described first embodiment, an optical element 1 having excellent antireflection characteristic can be obtained.

### 5. Fifth Embodiment

### Configuration of Optical Element

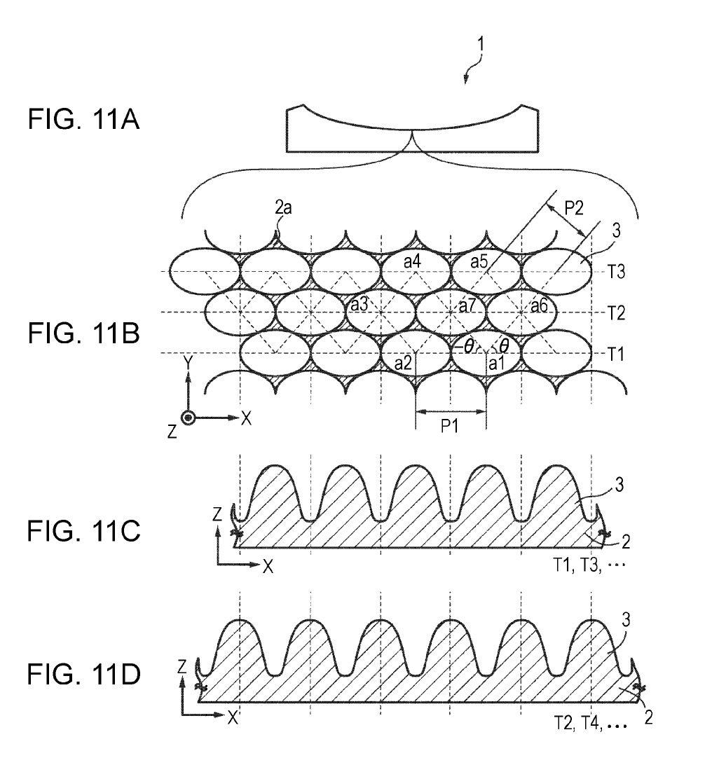

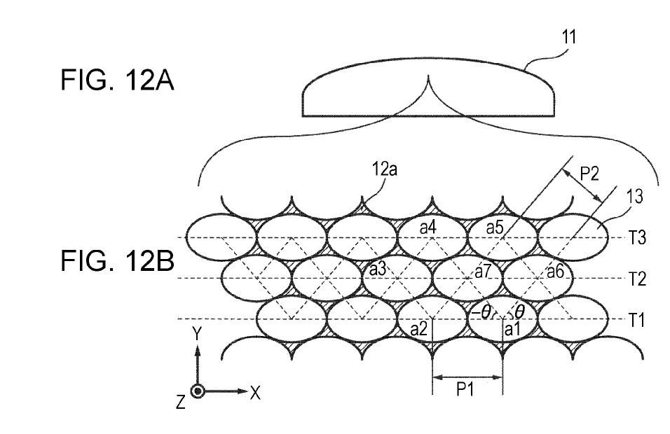

FIG. 11A is a schematic plan view showing an example of the configuration of an optical element according to a fifth embodiment of the present invention. FIG. 11B is a magnified plan view illustrating a part of the optical element shown in FIG. 12 A. FIG. 11C is a sectional view along a track T1, T3, . . . shown in FIG. 11B. FIG. 11D is a sectional view along a track T2, T4, . . . shown in FIG. 11 B.

An optical element 1 according to the fifth embodiment is different from the optical element 1 of the first embodiment in that a surface in the shape of a spherical surface is included and structures 3 are disposed on this spherical surface. The spherical surface is, for example, a convex or concave spherical surface. The optical element 1 is, for example, a concave lens or a convex lens. FIG. 11 shows the case where the optical element 1 has a concave spherical surface, as an example.

Regarding the optical element 1 according to the fifth embodiment, the items other than the above description are the same as those in the first embodiment.

### [Configuration of Master]

FIG. 12 shows an example of the configuration of a master for producing an optical element having the above-described configuration. A master 11 according to the fifth embodiment is different from the first embodiment in that a surface in the shape of a spherical surface is included and structures 13 are disposed on this spherical surface. The spherical surface is, for example, a convex or concave spherical surface. FIG. 12 shows the case where the master 11 has a convex spherical surface, as an example.

Regarding the master 11 according to the fifth embodiment, the items other than the above description are the same as those in the first embodiment.

### [Configuration of Exposing Apparatus]

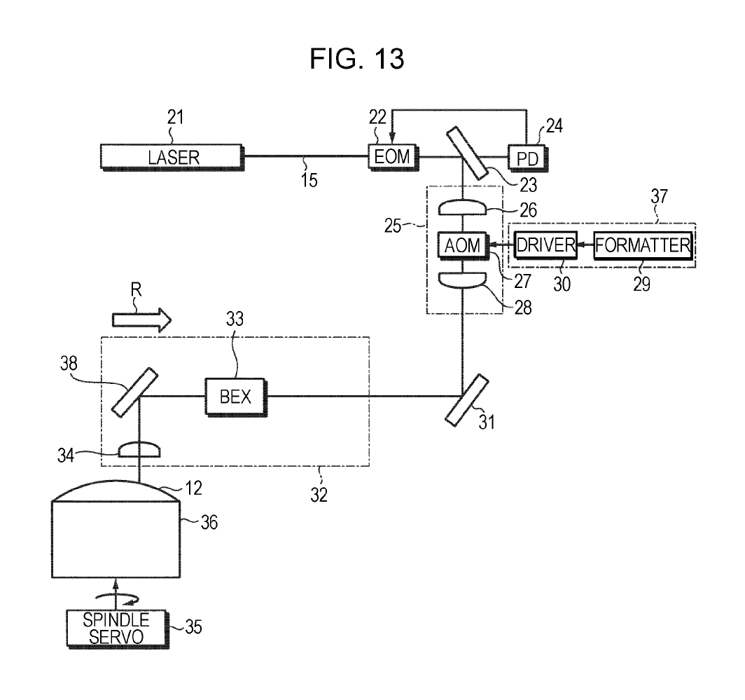

FIG. 13 is a schematic diagram showing an example of the configuration of an exposing apparatus for producing a master having the above-described configuration. A moving optical table 32 is provided with a beam expander 33, a mirror 38, and an objective lens 34. A position sensor (not shown in the drawing) is disposed at the position just below the objective lens 34. Collision with a spherical surface of a stamper 12 is prevented by this position sensor. The laser light 15 led to the moving optical table 32 is shaped into a desired beam shape with the beam expander 33 and, thereafter, is applied to a resist layer disposed on the spherical surface of the stamper 12 through the mirror 38 and the objective lens 34. The stamper 12 having the spherical surface is placed on a turn table 36 connected to a spindle motor 35. Then, the laser light is applied to the resist layer on the stamper 12 intermittently while the stamper 12 is rotated and, in addition, the laser light 15 is moved in the rotation radius direction of the stamper 12, so that an exposure step of the resist layer is performed. The movement of the laser light 15 is performed by moving the moving optical table 32 in the direction indicated by an arrow R.

Regarding the exposing apparatus according to the fifth embodiment, the items other than the above description are the same as those in the first embodiment.

### [Configuration of Etching Apparatus]

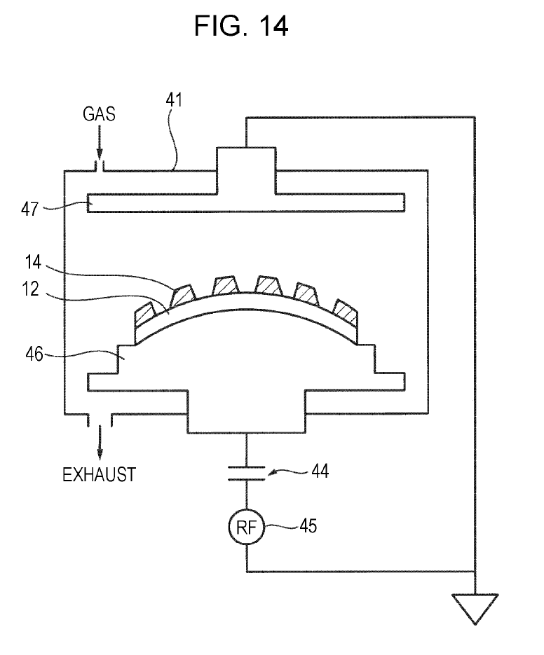

FIG. 14 is a schematic diagram showing an example of the configuration of an etching apparatus for producing a master having the above-described configuration. A spherical electrode 46 and a counter electrode 47 opposite to this spherical electrode 46 are provided in an etching reaction vessel 41. The spherical electrode 46 has a spherical surface on the side opposite to the counter electrode 47, and the stamper 12 is placed on this spherical surface. The spherical electrode 46 has a configuration, in which the spherical stamper 12 is removably attached thereto. The spherical electrode 46 has, for example, a spherical surface nearly identical or analogous to the spherical surface of the spherical stamper 12.

Regarding the etching apparatus according to the fifth embodiment, the items other than the above description are the same as those in the first embodiment.

### 6. Sixth Embodiment

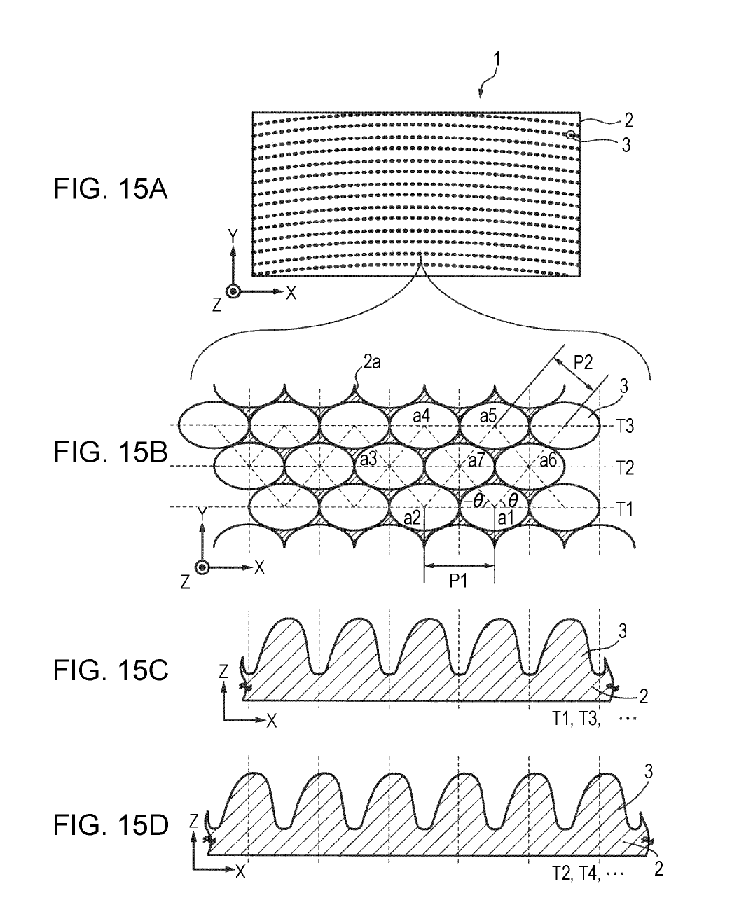

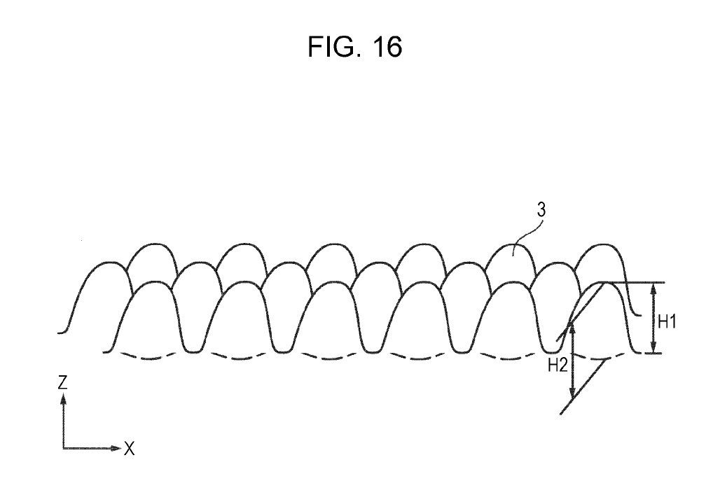

FIG. 15 A is a schematic plan view showing an example of the configuration of an optical element according to a sixth embodiment of the present invention. FIG. 15 B is a magnified plan view illustrating a part of the optical element shown in FIG. 15 A. FIG. 15 C is a sectional view along a track T1, T3, . . . shown in FIG. 15 B. FIG. 15 D is a sectional view along a track T2, T4, . . . shown in FIG. 15 B. FIG. 16 is a magnified perspective view illustrating a part of the optical element shown in FIG. 15.

The sixth embodiment is different from the first embodiment in that structures 3 are inclined with respect to the substrate surface. The structures 3 may point in at least two different directions with respect to the substrate surface. Specifically, the structures 3 may be formed inclining in at least two different directions at predetermined angles with respect to the normal to the substrate surface. Alternatively, the structures 3 may have a plurality of regions and the directions of the structures may be different depending on the individual regions.

Regarding the optical element according to the sixth embodiment, the items other than the above description are the same as those in the first embodiment.

### [Configuration of Master]

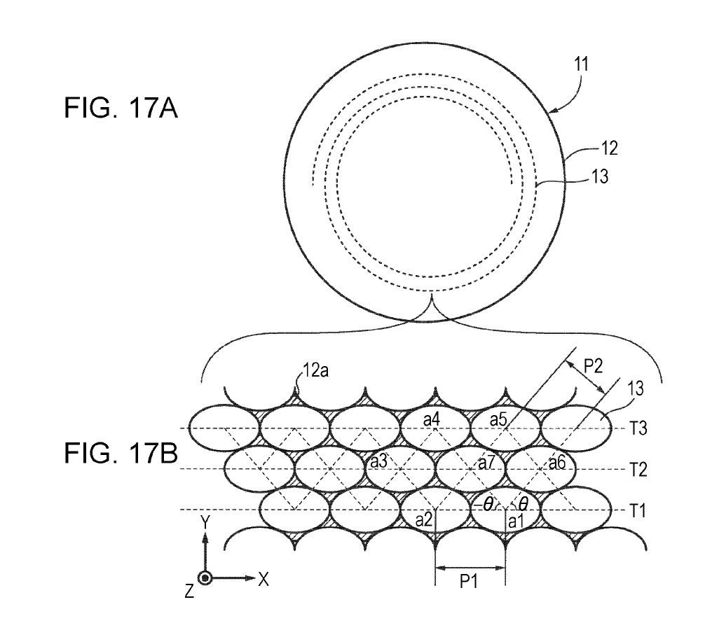

FIG. 17 shows an example of the configuration of a master for producing the optical element having the above-described configuration. As shown in FIG. 17, a master 11 has the configuration, in which a large number of structures 13 composed of concave portions are arranged on the surface of a stamper 12 in the shape of a disk. These structures 13 are periodically two-dimensionally arranged with a pitch smaller than or equal to the wavelength of the light in a use environment of the optical element 1, for example, with the same level of pitch as the wavelength of the visible light. The structures 13 are disposed on a track in the shape of concentric circles or the shape of a spiral.

Regarding the master according to the sixth embodiment, the items other than the above description are the same as those in the first embodiment.

### [Configuration of Exposing Apparatus]

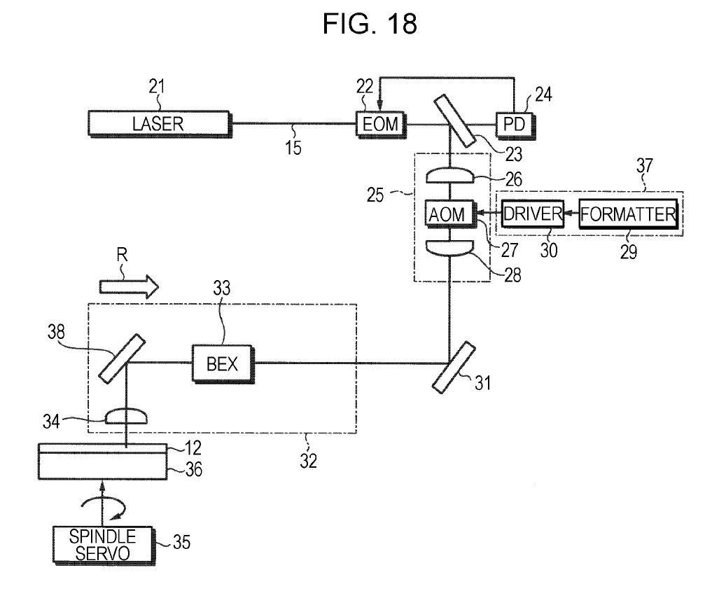

FIG. 18 is a schematic diagram showing an example of the configuration of an exposing apparatus for producing a master having the above-described configuration. The exposing apparatus according to the sixth embodiment is the same as that in the fifth embodiment. However, in the sixth embodiment, as shown in FIG. 18, a stamper 12 in the shape of a disk is placed on a turn table 36, the laser light is applied to an inorganic resist of this stamper 12, so that exposure is performed.

### [Configuration of Etching Apparatus]

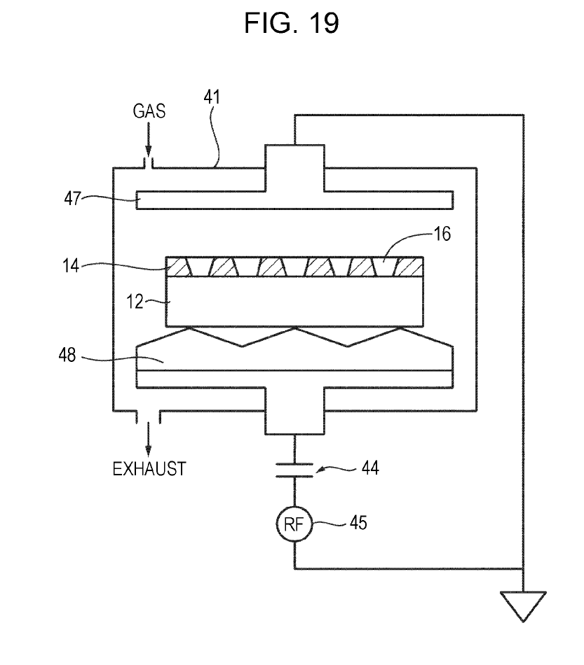

FIG. 19 is a schematic diagram showing an example of the configuration of an etching apparatus for producing a master having the above-described configuration. An uneven electrode 48 and a counter electrode 47 opposite to this uneven electrode 48 are provided in an etching reaction vessel 41. The uneven electrode 48 has an uneven surface on the side opposite to the counter electrode 47, and the stamper 12 is placed on this uneven surface.

In the etching apparatus having the above-described configuration, when a high-frequency voltage is applied between the counter electrode 47 and the uneven electrode 48 by the high-frequency power supply 45, an electric field is generated in the direction in accordance with the uneven surface of the uneven electrode 48 because of voltage drop. Positive ions in the plasma enter the principal surface of the stamper 12 in the shape of a disk in a slanting direction and the like, so that anisotropic etching is performed. In this regard, anisotropic etching of the stamper 12 can be performed in at least two different directions by adjusting the uneven shape of the uneven electrode 48 appropriately and using the uneven surface of the uneven electrode 48. Furthermore, it is also possible to change the direction of anisotropic etching in accordance with the regions of the surface of the stamper 12 by adjusting the uneven shape of the uneven electrode 48 appropriately and using the uneven surface of the uneven electrode 48.

Regarding the etching apparatus according to the sixth embodiment, the items other than the above description are the same as those in the first embodiment.

### [Method for Manufacturing Optical Element]

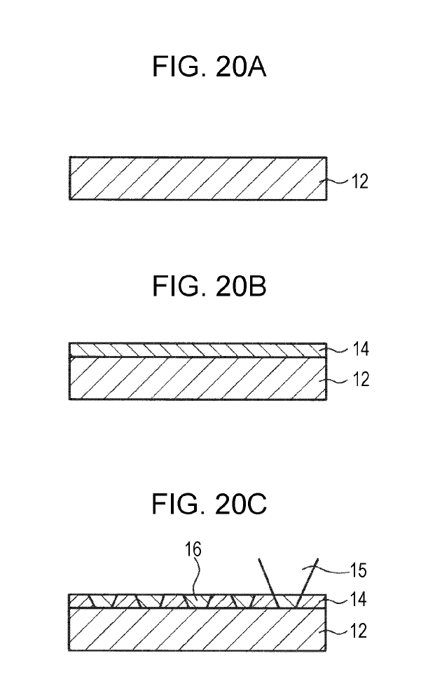

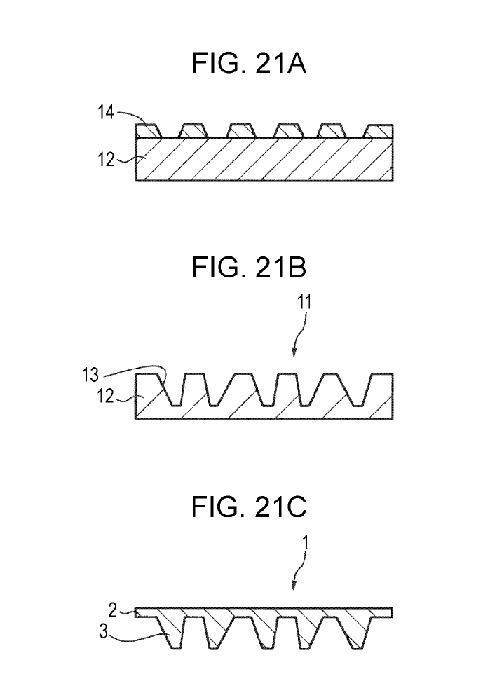

A method for manufacturing an optical element according to the sixth embodiment of the present invention will be described with reference to FIG. 20 and FIG. 21.

### (Resist Film Formation Step)

Initially, as shown in FIG. 20 A, a stamper 12 in the shape of a disk is prepared. This stamper 12 is, for example, a glass stamper. Subsequently, as shown in FIG. 20 B, an inorganic resist layer 14 is formed on one principal surface of the stamper 12 in the shape of a disk by a sputtering method. As for the inorganic resist, for example, a metal oxide formed from at least one type of transition metal, e.g., tungsten and molybdenum, can be used.

### (Exposure Step)

Then, as shown in FIG. 20 C, the exposing apparatus shown in FIG. 18 is used, the stamper 12 is rotated and, in addition, the laser light (exposure beam) 15 is applied to the inorganic resist layer 14. At this time, the laser light 15 is applied intermittently while the laser light 15 is moved in the height direction of the stamper 12 and, thereby, all over the surface of the inorganic resist layer 14 is exposed. In this manner, a latent image 16 in accordance with the locus of the laser light 15 is formed all over the inorganic resist layer 14 with, for example, the same level of pitch as the wavelength of the visible light.

### (Development Step)

Next, a developing solution is dropped on the inorganic resist layer 14 while the stamper 12 is rotated, so that the inorganic resist layer 14 is subjected to a developing treatment, as shown in FIG. 21A. In the case where the inorganic resist layer 14 is formed from a positive type resist, the exposed portion exposed with the laser light 15 has an increased dissolution rate with respect to the developing solution as compared with that of the non-exposed portion. Therefore, as shown in FIG. 21A, a pattern in accordance with the latent image (exposed portion) 16 is formed on the inorganic resist layer 14.

### (Etching Step)

Subsequently, the etching apparatus shown in FIG. 19 is used, and the surface of the stamper 12 is subjected to an etching treatment while the pattern (resist pattern) of the inorganic resist layer 14 formed on the stamper 12 serves as a mask. In this manner, as shown in FIG. 21B, structures 13 pointing various directions, e.g., slanting directions, with respect to the one principal surface of the stamper 12 in the shape of a disk are formed. Moreover, as necessary, the etching treatment and an ashing treatment may be performed alternately. Consequently, the structures 13 having various curved surfaces can be formed.

In this manner, a master 11, in which the structures 3 are disposed pointing slanting direction and the like with respect to the substrate surface, can be obtained.

### (Duplicate Step)

Then, the master 11 and the substrate 2, e.g., an acrylic sheet coated with an ultraviolet curable resin, are closely adhered, and ultraviolet rays are applied, so as to cure the ultraviolet curable resin. Thereafter, the substrate 2 is peeled off the master 11. In this manner, as shown in FIG. 21C, a desired optical element 1 is produced.

### 7. Seventh Embodiment

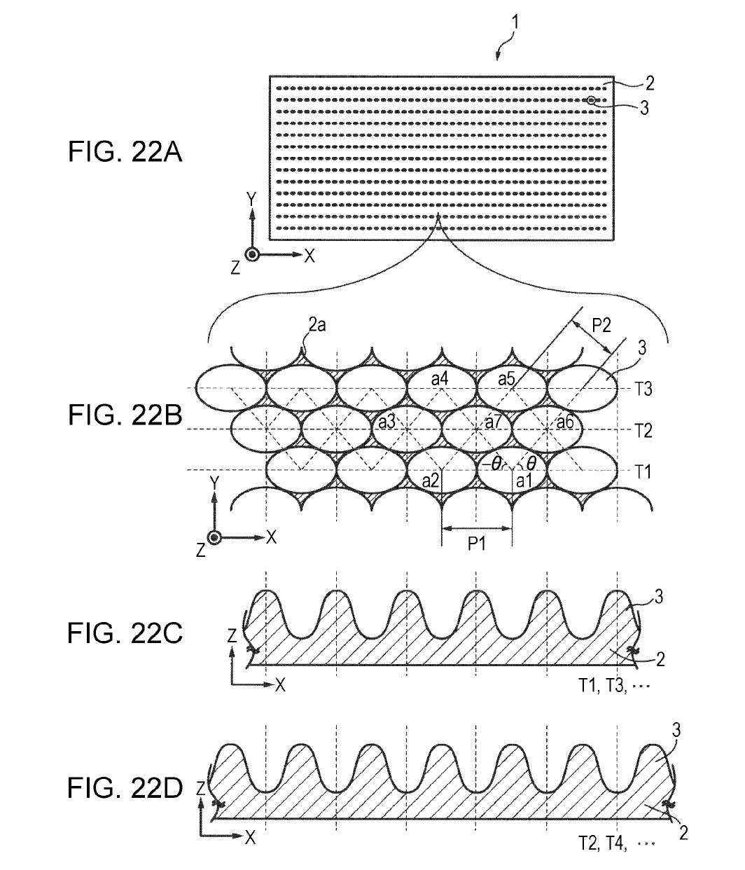

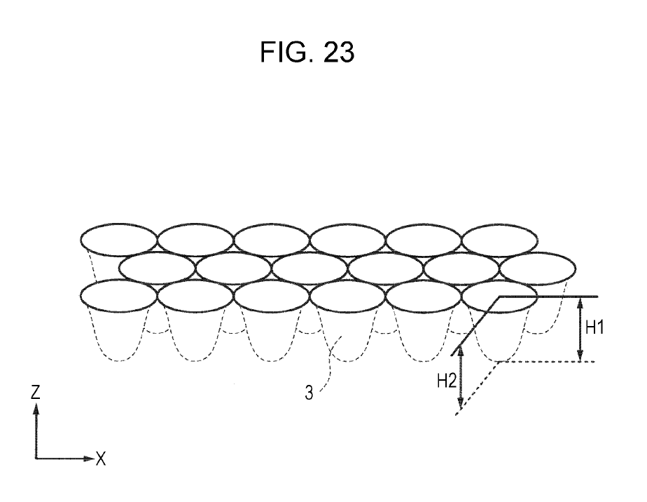

FIG. 22 A is a schematic plan view showing an example of the configuration of an optical element according to a seventh embodiment of the present invention. FIG. 22 B is a magnified plan view illustrating a part of the optical element shown in FIG. 22 A. FIG. 19 C is a sectional view along a track T1, T3, . . . shown in FIG. 22 B. FIG. 22 D is a sectional view along a track T2, T4, . . . shown in FIG. 19 B. FIG. 23 is a magnified perspective view illustrating a part of the optical element shown in FIG. 22.

An optical element 1 according to the seventh embodiment is different from the optical element 1 of the first embodiment in that a large number of structures 3 composed of concave portions are arranged on the substrate surface. The shape of this structure 3 is a concave shape corresponding to inversion of the convex shape of the structure 3 in the first embodiment.

### 8. Eighth Embodiment

An eighth embodiment is different from the first embodiment in that an uneven pattern produced by subjecting an inorganic resist layer 14 to a developing treatment is directly used as a master.

Specifically, an optical element is produced as described below.

Initially, the steps from the resist film formation step to the development step are performed in a manner similar to that in the first embodiment. Consequently, hexagonal lattice pattern or quasi-hexagonal lattice pattern concave portions are formed on the inorganic resist layer 14. Subsequently, a stamper 12 provided with such a pattern on the inorganic resist layer 14 is used as a master and an optical element 1 is produced as described below. That is, this master and a substrate 2, e.g., an acrylic sheet coated with an ultraviolet curable resin, are closely adhered, and ultraviolet rays are applied, so as to cure the ultraviolet curable resin. Thereafter, the substrate 2 is peeled off the master 11.

Regarding the eighth embodiment, the items other than the above description are the same as those in the first embodiment.

According to the eighth embodiment, a highly rigid inorganic resist layer 14 is formed on a stamper 12, e.g., a metal stamper or a sheet, by a sputtering method, the resulting inorganic resist layer 14 is subjected to exposure and development and, thereby, an uneven pattern is formed on the inorganic resist layer 14. Consequently, the stamper 12 having the uneven pattern of the inorganic resist layer 14 can be directly used as a stamper.

On the other hand, in the case where an organic resist is used, the organic resist is soft and, therefore, it is difficult to use the original having an uneven pattern of the organic resist as a stamper. Consequently, it is necessary to produce an uneven pattern stamper by forming an electrically conductive film layer on the organic resist original (uneven pattern) and, thereafter, forming a nickel plating layer by an electroplating method, and peeling it. Furthermore, as necessary, trimming into a predetermined size may be performed. As described above, in the case where the organic resist is used, complicated steps are required until the stamper is completed.

### 9. Ninth Embodiment

### Configuration of Liquid Crystal Display Device

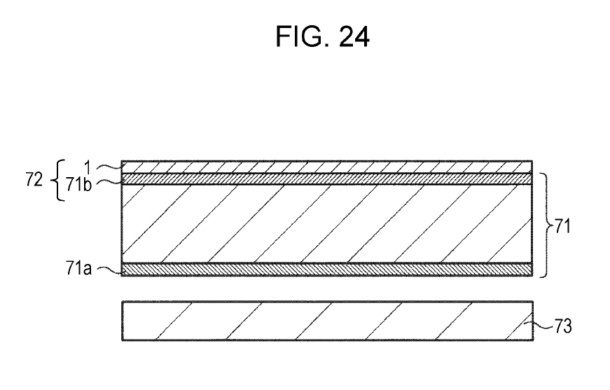

FIG. 24 shows an example of the configuration of a liquid crystal display device according to a ninth embodiment of the present invention. As shown in FIG. 24, this liquid crystal display device is provided with a backlight 73 to emit light and a liquid crystal panel 71 to temporally spatially modulate the light emitted from the backlight 73 and display an image. Polarizers 71a and 71b are disposed on two surfaces of the liquid crystal panel 71, respectively. An optical element 1 is provided on the polarizer 71b disposed on the display surface side of the liquid crystal panel 71. In the present invention, the polarizer 71b provided with the optical element 1 on one principal surface is referred to as a polarizer 72 with antireflection function. This polarizer 72 with antireflection function is an example of optical components with antireflection function.

The backlight 73, the liquid crystal panel 71, the polarizers 71a and 71b, and optical element 1, which constitute the liquid crystal display device, will be sequentially described below.

### (Backlight)

As for the backlight 73, for example, a direct backlight, an edge backlight, and a plane light source type backlight can be used. The backlight 73 is provided with, for example, a light source, reflection plate, and an optical film. As for the light source, for example, a cold cathode fluorescent lamp (Cold Cathode Fluorescent Lamp: CCFL), a hot cathode fluorescent lamp (Hot Cathode Fluorescent Lamp: HCFL), organic electroluminescence (Organic Electroluminescence: OEL), inorganic electroluminescence (IEL: Inorganic Electroluminescence), and a light emitting diode (Light Emitting Diode: LED) are used.

### (Liquid Crystal Panel)

As for the liquid crystal panel 71, those having a display mode of, for example, twisted nematic (Twisted Nematic: TN) mode, super twisted nematic (Super Twisted Nematic: STN) mode, vertically aligned (Vertically Aligned: VA) mode, in-plane switching (In-Plane Switching: IPS) mode, optically compensated birefringence (Optically Compensated Birefringence: OCB) mode, ferroelectric liquid crystal (Ferroelectric Liquid Crystal: FLC) mode, polymer dispersed liquid crystal (Polymer Dispersed Liquid Crystal: PDLC) mode, and phase change guest host (Phase Change Guest Host: PCGH) mode can be used.

### (Polarizer)

On two surfaces of the liquid crystal panel 71, for example, polarizers 71a and 71b are disposed in such a way that transmission axes thereof become orthogonal to each other. The polarizers 71a and 71b transmit merely one of orthogonal polarized components in the incident light and interrupt the other through absorption. As for the polarizers 71a and 71b, for example, those produced by adsorbing dichroic materials, e.g., iodine or dichroic dyes, to hydrophilic polymer films, e.g., polyvinyl alcohol based films, partially formalized polyvinyl alcohol based films, and ethylene-vinyl acetate copolymer based partially saponified films, and performing uniaxial stretching can be used. It is preferable that protective layers, e.g., triacetyl cellulose (TAC) films, are disposed on both surfaces of the polarizers 71a and 71b. In the case where the protective layer is disposed, as described above, it is preferable that a structure, in which the substrate 2 of the optical element 1 doubles as a protective layer, is employed. The reason therefor is that the thickness of a polarizer 72 with antireflection function can be reduced by employing such a structure.

### (Optical Element)

The optical element 1 is the same as any one of the optical element 1 in the above-described first to fourth, sixth, and seventh embodiments and, therefore, the explanation will be omitted.

According to the ninth embodiment, the optical element 1 is disposed on the display surface of the liquid crystal display device and, therefore, the antireflection function of the display surface of the liquid crystal display device can be improved. Consequently, the visibility of the liquid crystal display device can be improved.

### 10. Tenth Embodiment

### Configuration of Liquid Crystal Display Device

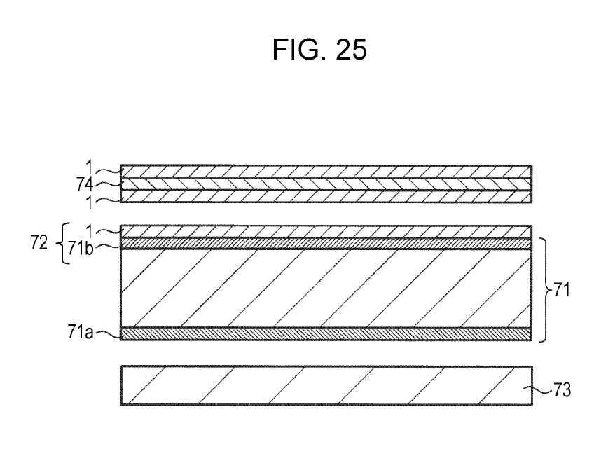

FIG. 25 shows an example of the configuration of a liquid crystal display device according to a tenth embodiment of the present invention. As shown in FIG. 25, this liquid crystal display device is different from the liquid crystal display device in the ninth embodiment in that a front member 74 is provided on the front side of a liquid crystal panel 71 and an optical element 1 is provided on at least one surface of the front of the liquid crystal panel 71 and the front and the back of the front member 74. In FIG. 25, an example, in which optical elements 1 are provided on all surfaces of the front of the liquid crystal panel 71 and the front and the back of the front member 74, is shown. For example, an air layer is disposed between the liquid crystal panel 71 and the front member 74. The same portions as those in the above-described ninth embodiment are indicated by the same reference numerals as those set forth above and explanations thereof will be omitted. In this regard, in the present invention, the front refers to the surface on the side serving as a display surface, that is, the surface on the observer side, and the back refers to the surface on the side opposite to the display surface.

The front member 74 is, for example, a front panel used on the front (observer side) of the liquid crystal panel 71 for the purpose of mechanical, thermal, and weather-resistant protection and design. The front member 74 has, for example, the shape of a sheet, the shape of a film, or the shape of a plate. As for the materials for the front member 74, for example, glass, triacetyl cellulose (TAC), polyester (TPEE), polyethylene terephthalate (PET), polyimide (PI), polyamide (PA), aramid, polyethylene (PE), polyacrylate, polyether sulfone, polysulfone, polypropylene (PP), diacetyl cellulose, polyvinyl chloride, acrylic resin (PMMA), and polycarbonate (PC) can be used, although not specifically limited to these materials. Any material can be used insofar as the material has transparency.

According to the tenth embodiment, the visibility of the liquid crystal display device can be improved as in the ninth embodiment.

### EXAMPLES

The present invention will be specifically described below with reference to the examples, although the present invention is not limited to merely these examples.

### Example 1

Initially, an inorganic resist layer composed of oxides of tungsten (W) and molybdenum (Mo) was formed on a quartz substrate in the shape of a disk by a sputtering method. Subsequently, a latent image of quasi-hexagonal lattice pattern was formed on the resulting inorganic resist layer by using the exposing apparatus shown in FIG. 18. Thereafter, the resist layer was subjected to a developing treatment, so as to produce a resist pattern. As for a developing solution, a 2.38% tetramethylammonium hydroxide aqueous solution (TOKYO OHKA KOGYO CO., LTD.) was used.

Then, a process for etching the quartz substrate through RIE etching and a process for removing the resist pattern and increasing the opening diameter through ashing were performed repeatedly. In this regard, etching was performed by using the etching apparatus having the uneven electrode shown in FIG. 19. By the above-described step, etching proceeded in a slanting direction and the like with respect to the quartz substrate surface while the diameter of the quasi-hexagonal lattice pattern, at which the surface of the quartz substrate was exposed, was increased gradually. The other regions were not etched because the resist pattern served as a mask. Consequently, concave portions pointing in the slanting direction and the like with respect to the surface of the quartz substrate were formed. Finally, the resist pattern was removed completely through ashing. In this manner, a desired disk master was obtained.

Next, an ultraviolet curable resin was applied to the resulting disk master and, thereafter, an acrylic plate was closely adhered to the ultraviolet curable resin. Subsequently, ultraviolet rays were applied, so that the ultraviolet curable resin was cured and peeled off the disk master. In this manner, a desired optical element was obtained.

### (Example 2)

A duplicate substrate was obtained as in Example 1 except that the uneven shape of the uneven electrode of the etching apparatus was changed.

### Example 3

Initially, a glass roll stamper having an outside diameter of 126 mm was prepared. An inorganic resist layer composed of oxides of tungsten (W) and molybdenum (Mo) was formed on the surface of this glass roll stamper by a sputtering method. Subsequently, the glass roll stamper serving as a recording medium was carried to the exposing apparatus shown in FIG. 4, and the inorganic resist layer was exposed. Consequently, a latent image continuing in the shape of a spiral and constituting a quasi-hexagonal lattice pattern with respect to adjacent three lines of tracks was patterned on the resist.

Thereafter, the inorganic resist layer on the glass roll stamper was subjected to a developing treatment, in which development was performed by dissolving the exposed portion of the resist. Specifically, an undeveloped glass roll stamper was placed on a turn table of a developing machine, although not shown in the drawing, a developing solution was dropped on the surface of the glass roll stamper while rotation was performed on a turn table basis, so as to develop the resist on the surface. In this manner, a resist glass stamper, in which the resist layer was exposed at the quasi-hexagonal lattice pattern, was obtained. In this regard, as for the developing solution, a 2.38% tetramethylammonium hydroxide aqueous solution (TOKYO OHKA KOGYO CO., LTD.) was used.

Then, a process for etching the glass roll stamper through RIE etching and a process for removing the resist pattern and increasing the opening diameter through ashing were performed repeatedly. In this regard, etching was performed by using the etching apparatus having the circular cylindrical electrode shown in FIG. 5. By the above-described step, etching proceeded in a direction perpendicular to the glass roll stamper surface while the diameter of the quasi-hexagonal lattice pattern, at which the surface of the glass roll stamper was exposed, was increased gradually. The other regions were not etched because the resist pattern served as a mask. Consequently, concave portions pointing in the direction perpendicular to the surface of the glass roll stamper were formed. Finally, the resist pattern was removed completely through ashing. In this manner, a desired glass roll master was obtained.

Next, the resulting glass roll stamper was closely adhered to an acrylic plate coated with an ultraviolet curable resin. Peeling was performed while ultraviolet rays were applied to effect curing, so that an optical element was produced.

### (Evaluation of Shape)

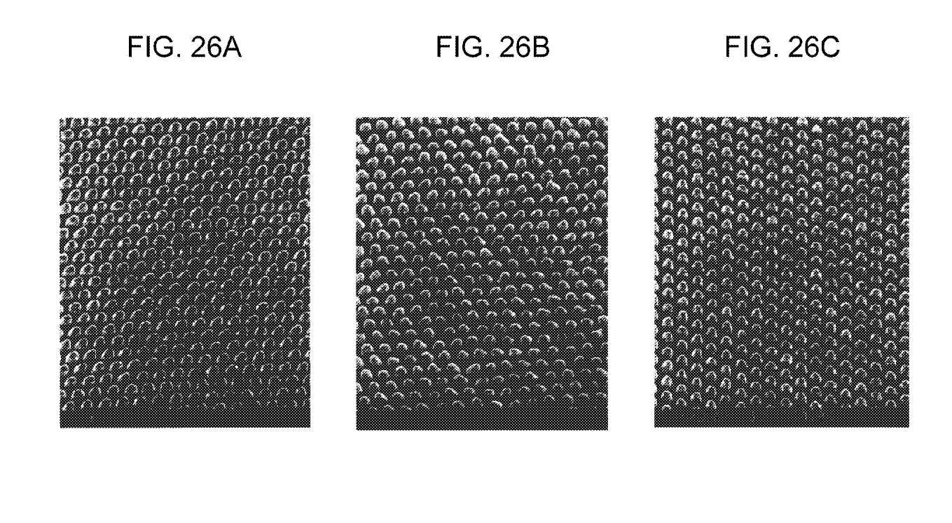

Observation of the thus produced optical element was performed with a scanning electron microscope (SEM: Scanning Electron Microscope). The results thereof are shown in FIG. 26.

As is clear from FIG. 26 A and FIG. 26 B, in the case where etching is performed by using the uneven electrode, structures can be formed in a slanting direction with respect to the substrate. Furthermore, it is clear that the direction of the structures can be changed in accordance with the regions by adjusting the uneven shape of the uneven electrode appropriately.

As is clear from FIG. 26 C, in the case where etching is performed by using the circular cylindrical electrode, structures can be formed in a direction perpendicular to the substrate.

### (Evaluation of Reflectance)

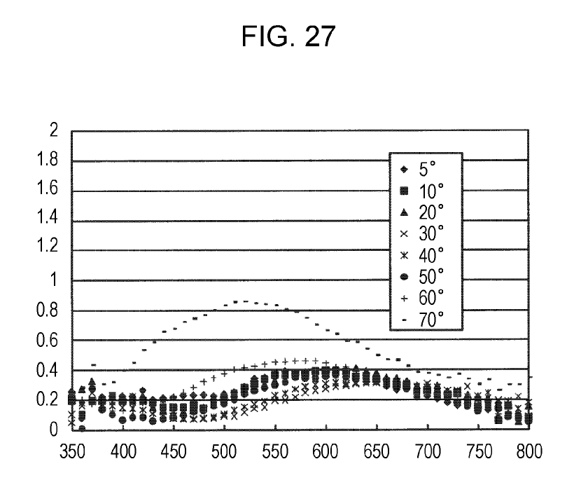

The reflectance of the optical element produced as described above in Example 1 was measured. In this regard, an ultraviolet and visible spectrophotometer (trade name: V-550 produced by JASCO Corporation) was used for the measurement of the reflectance. The results thereof are shown in FIG. 27.

The following is clear from FIG. 27.

There is a tendency that the reflectance of the light with an incident angle of 30 degrees or 40 degrees is reduced as compared with the reflectance of the light with an incident angle of 5 degrees. That is, regarding the optical element in Example 1, the effect of antireflection characteristic becomes most significant with respect to the light with an incident angle of 30 degrees or 40 degrees. This is because regarding the optical element in Example 1, the structures are disposed while being inclined about 30 degrees to 40 degrees with respect to the normal to the substrate.

As described above, angle dependence can be given to the antireflection characteristic of the optical element by forming the structures in such a way as to incline with respect to the normal to the substrate. The optical element having such a characteristic is effective in the case where it is desired to particularly reduce the reflectance of the light incident from a predetermined angle.

### Example 4

Initially, an optical element in the shape of a band was produced as in Example 3. Subsequently, an optical element in the shape of a predetermined rectangle was cut from the resulting optical element in the shape of a band.

Then, the resulting optical element in the shape of a rectangle was bended into the shape of a spherical surface

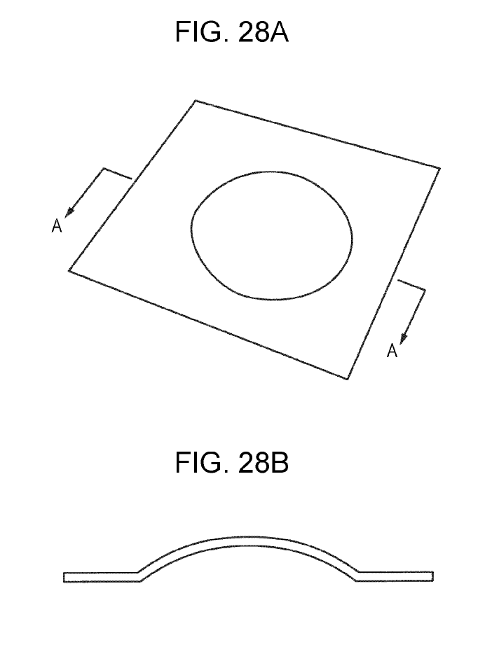

in a warm bath at a temperature of 80° C., so as to obtain a moth-eye lens film. FIG. 28 A and FIG. 28 B show an outward appearance and a sectional view, respectively, of a moth-eye lens film obtained as described above.

### (Evaluation of Reflection Characteristic)

The reflectance of the moth-eye lens film produced as described above in Example 4 was measured. In this regard, an ultraviolet and visible spectrophotometer (trade name: V-550 produced by JASCO Corporation) was used for the measurement of the reflectance. It was made clear from the evaluation result that regarding the moth-eye lens film in Example 4, excellent antireflection characteristic was obtained.

### Example 5

Initially, a quartz lens (convex lens) having a spherical surface was prepared. An inorganic resist layer composed of oxides of tungsten (W) and molybdenum (Mo) was formed on this spherical surface of the quartz lens serving as a stamper by a sputtering method. Subsequently, the stamper serving as a recording medium was carried to the exposing apparatus shown in FIG. 13, and a latent image of a quasi-hexagonal lattice pattern was formed. Thereafter, the resist layer was subjected to a developing treatment, so as to produce a resist pattern. As for the developing solution, a 2.38% tetramethylammonium hydroxide aqueous solution (TOKYO OHKA KOGYO CO., LTD.) was used.

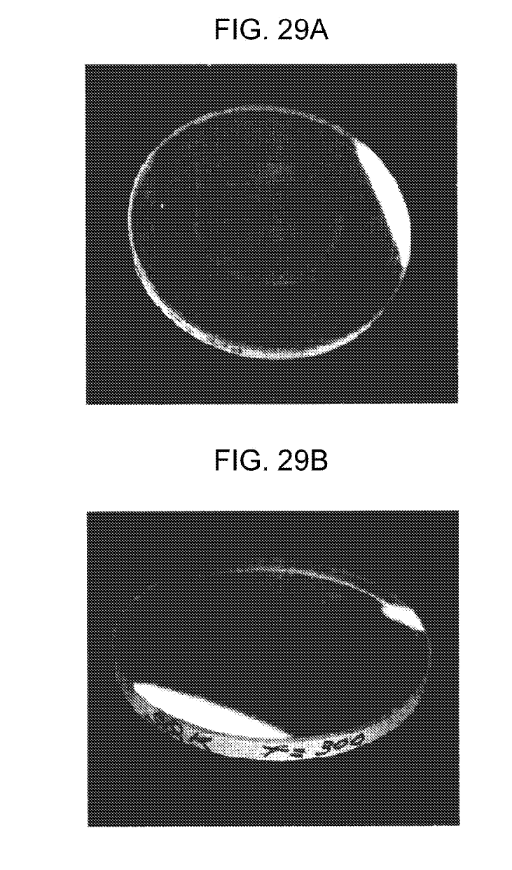

Then, a process for etching the stamper through RIE etching and a process for removing the resist pattern and increasing the opening diameter through ashing were performed repeatedly. In this regard, etching was performed by using the etching apparatus having the spherical electrode shown in FIG. 14. By the above-described step, etching proceeded in regions, in which the stamper surface was exposed at the inorganic resist layer, while the diameter of the quasi-hexagonal lattice pattern was increased gradually. The other regions were not etched because the inorganic resist layer served as a mask. Finally, the inorganic resist layer was removed completely through ashing. In this manner, a desired moth-eye quartz lens was obtained. FIG. 29 A and FIG. 29 B show the outward appearance of the moth-eye quartz lens obtained as described above.

### (Evaluation of Reflection Characteristic)

The reflectance of the moth-eye quartz lens produced as described above in Example 5 was measured. In this regard, an ultraviolet and visible spectrophotometer (trade name: V-550 produced by JASCO Corporation) was used for the measurement of the reflectance. It was made clear from this evaluation result that regarding the moth-eye quartz lens in Example 5, excellent antireflection characteristic was obtained.

Up to this point, the embodiments according to the present invention have been specifically described. However, the present invention is not limited to the above-described embodiments, and various modifications can be made on the basis of the technical idea of the present invention.

For example, the configurations, the shapes, the numerical values, and the like are no more than examples, and as necessary, configurations, shapes, numerical values, and the like different from them may be employed.

Furthermore, the individual configurations of the above-described embodiments can be combined with each other within the bounds of not departing from the gist of the present invention.

Moreover, in the above-described embodiments, examples of application of the present invention to the stampers having curved surfaces (the shape of a circular cylinder, the shape of a sphere) are described, although the present invention is not limited to these examples. For example, it is possible that regarding a stamper having the shape of a sheet, a tape (both surfaces), or a rod, or the shape of a needle, a desired uneven pattern is formed on the stamper, so as to form a master.

In addition, it is possible to produce a desired uneven pattern on a surface of a box (rectangular parallelepiped) or a wire frame, an inside of a circular cylinder or a box, or the like. That is, a flat and smooth resist film having a uniform film thickness is disposed by forming a film of an inorganic resist on a surface of a box (rectangular parallelepiped) or a wire frame, an insides of a circular cylinder or a box, or the like by a sputtering method. Subsequently, the inorganic resist film is exposed with a stepper, various patterns are recorded, and development is performed, so that an uneven pattern can be formed.

Furthermore, it is also possible to form a desired uneven pattern by forming a flat and smooth inorganic resist film having a uniform film thickness on an elliptical sphere (rugby ball type), the shape of a cone, a stamper having a large number of holes, a stamper having concave portions, a stamper having convex portions, or the like, and performing exposure and development.

Moreover, it is also possible to apply to uneven substrates and devices, which are used for displays and the like, or substrates and devices, which have the shapes of waves or curved surfaces.

In this regard, in the above-described embodiments, an uneven shape may be formed on a surface of the circular cylindrical electrode and the spherical electrode. Consequently, structures can be formed in a slanting direction and the like with respect to the surfaces of the stamper in the shape of a circular cylinder and the stamper in the shape of a spherical surface.

In addition, in the above-described embodiments, explanation has been made with reference to the case where the electrodes of the optical element and the etching apparatus are in the shape of a circular cylindrical surface and the shape of a spherical surface, as an example. However the shapes of the electrodes of the optical element and the etching apparatus are not limited to them. As for the shapes of the curved surface other than them, various curved surfaces, e.g., a hyperboloid, a free-form surface, and an elliptical surface, can be employed.

Furthermore, in the above-described embodiments, explanation has been made relative to the case where the optical elements and the like are produced by using the inorganic resist. However, it is also possible to employ an organic resist.

1. A method for manufacturing a microfabricated member, the method comprising the steps of:
forming an inorganic resist layer on a stamper having a curved surface;
exposing and developing the inorganic resist layer formed on the stamper, so as to form a pattern on the inorganic resist layer; and
placing the stamper, which is provided with the pattern on the inorganic resist layer, on an electrode having a curved surface nearly identical or analogous to the curved surface of the stamper and etching the stamper to form an uneven shape on the stamper surface, so as to produce a microfabricated member.

2. The method for manufacturing a microfabricated member according to claim 1, wherein the stamper has the shape of a circular cylinder or the shape of a spherical surface.

3. The method for manufacturing a microfabricated member according to claim 1,
wherein an uneven shape is formed on the curved surface of the electrode, and
in the step to etch, anisotropic etching is performed in a slanting direction with respect to the surface of the stamper by using the uneven shape of the electrode.

4. The method for manufacturing a microfabricated member according to claim 3, wherein in the step to etch, the stamper is anisotropically etched in at least two different directions by using the uneven shape of the electrode.

5. The method for manufacturing a microfabricated member according to claim 4, wherein in the step to etch, the direction of anisotropic etching is changed in accordance with regions of the surface of the stamper by using the uneven shape of the electrode.

6. The method for manufacturing a microfabricated member according to claim 1, wherein in the step to form the inorganic resist layer, the inorganic resist layer is formed by a sputtering method.

7. The method for manufacturing a microfabricated member according to claim 1, the method further comprising the step of transferring the uneven shape of the microfabricated member to a resin material after the step to produce the microfabricated member, so as to produce a duplicate of the microfabricated member.

8. A microfabricated member comprising:
a substrate having a curved surface; and
structures, which are convex portions or concave portions, formed on the curved surface of the substrate,
wherein the structures are arranged with a pitch less than or equal to the wavelength of the light in a use environment.

9. The microfabricated member according to claim 8, wherein the structures are disposed in a slanting direction with respect to the substrate surface.

10. The microfabricated member according to claim 9, wherein the structures are disposed in at least two different directions with respect to the substrate surface.

11. The microfabricated member according to claim 10, wherein the structures are disposed in different directions depending on regions of the substrate surface.

12. The microfabricated member according to claim 8,
wherein the structure has the shape of a cone, and
the structures are two-dimensionally arranged on the substrate surface.

13. The microfabricated member according to claim 12, wherein the structures are arranged periodically in the shape of a hexagonal lattice or in the shape of a quasi-hexagonal lattice.

14. The microfabricated member according to claim 12, wherein the structures are arranged periodically in the shape of a tetragonal lattice or in the shape of a quasi-tetragonal lattice.

15. The microfabricated member according to claim 12, wherein the shape of a cone is the shape of a circular cone or the shape of an elliptical cone, which have a curvature at the top portion, the shape of a circular truncated cone, or the shape of an elliptical truncated cone.

16. An etching apparatus comprising:
an etching reaction vessel; and
a first electrode and a second electrode, which are oppositely disposed in the etching reaction vessel,
wherein the first electrode has a placement surface for placing a substrate and
the placement surface has a curved surface or an uneven surface.

17. The etching apparatus according to claim 16, wherein the placement surface has the shape of a circular cylinder or the shape of a sphere.

18. An optical element comprising:
a substrate; and
a large number of structures arranged on a surface of the substrate,
wherein the structures are arranged with a pitch less than or equal to the wavelength of the light in a use environment, and
the structures are disposed slantingly in at least two different directions at predetermined angles with respect to the direction normal to the surface of the substrate.
